(19) United States
(12) Patent Application Publication
(10) Pub. No.: US 2008/0237696 A1
(43) Pub. Date: Oct. 2, 2008

(54) ALIGNMENT PROTECTION IN NON-VOLATILE MEMORY AND ARRAY

(76) Inventor: Chih-Hsin Wang, San Jose, CA (US)

Correspondence Address: HARNESS, DICKEY & PIERCE P.L.C., 5445 CORPORATE DRIVE, SUITE 200, TROY, MI, 48098, US

(21) Appl. No.: 11/933,377

(22) Filed: Oct. 31, 2007

Related U.S. Application Data
(63) Continuation-in-part of application No. 11/169,399, filed on Jun. 28, 2005.
Application No. 11/169,399 is a continuation-in-part of application No. 11/007,907, filed on Dec. 8, 2004, now Pat. No. 7,115,942.
Application No. 11/007,907 is a continuation-in-part of application No. 11/120,691, filed on May 2, 2005.
(60) Provisional application No. 60/585,238, filed on Jul. 1, 2004.
(60) Provisional application No. 60/626,326, filed on Nov. 8, 2004.
(60) Provisional application No. 60/942,571, filed on Jun. 7, 2007.

(51) Int. Cl. H01L 29/786

(52) U.S. Cl. 257/324; 257/E29.274

(57) ABSTRACT

A memory device, a memory array and a method of arranging memory devices and arrays. The memory device includes a memory region including a plurality of memory cells, each memory cell with a source, a drain and a channel between the source and the drain, a channel dielectric, a charge storage region and an electrically alterable conductor-material system in proximity to the charge storage region. The memory device includes a plurality of conductor lines. The memory includes a non-memory region having embedded logic including a plurality of transistors, each transistor for electrically coupling one of the conductor lines and each transistor including a transistor source, a transistor drain and a transistor gate.

### CROSS-REFERENCED APPLICATION

This application is a continuation-in-part of patent application Ser. No. 11/169,399, filed Jun. 28, 2005; US 2006/0001053 entitled METHOD AND APPARATUS TRANSPORTING CHARGES IN SEMICONDUCTOR DEVICE AND SEMICONDUCTOR MEMORY DEVICE, Pub. Date: Jan. 5, 2006; Inventor: Chih-Hsin Wang. The 11/169,399 application is a continuation-in-part of application Ser. No. 11/007,907 filed Dec. 8, 2004. The 11/169,399 application is a continuation-in-part of application Ser. No. 11/120,691 filed May 2, 2005. The 11/169,399 application claims the benefit under 35 USC 119(e) of application Ser. No. 60/585,238 filed Jul. 1, 2004. The 11/169,399 application claims the benefit under 35 USC 119(e) of application Ser. No. 60/626,326 filed Nov. 8, 2004. Application Ser. Nos. 11/169,399; 11/007,907; 11/120,691; 60/585,238; and 60/626,326 are hereby incorporated by reference in each of their entireties in the present application.

This application claims the benefit under 35 USC 119(e) of Provisional Patent Application U.S. Ser. No. 60/942,571 entitled METHOD FOR MANUFACTURING MEMORY, filed Jun. 7, 2007; Inventor: Chih-Hsin Wang. Application Ser. No. 60/942,571 is hereby incorporated by reference in its entirety in the present application.

### TECHNICAL FIELD

The present specification relates to semiconductor devices and semiconductor memory devices and to methods for arranging electrically alterable non-volatile memories and arrays.

### BACKGROUND

Non-volatile semiconductor memory cells permitting charge storage capability are well known in the art. The charges are typically stored in a floating gate to define the states of a memory cell. The states can be two levels or more than two levels (for multi-level state storage). Mechanisms such as channel hot electron injection (CHEI), source-side injection (SSI), Fowler-Nordheim tunneling (FN), and Band-to-Band Tunneling (BTBT) induced hot-electron-injection can be used to alter the states of such cells in program and/or erase operations. Examples employing such mechanisms for memory operations are described in U.S. Pat. Nos. 4,698,787, 5,029,130, 5,792,670 and 5,966,329 for CHEI, SSI, FN, and BTBT mechanisms, respectively.

All the above mechanisms, however, have poor injection efficiency (defined as the ratio of number of carriers collected to the number of carriers supplied). Further, these mechanisms require high voltages to support the memory operation, and a voltage as high as 10V is often seen. It is believed that the high voltage demands stringent control on the quality of the insulator surrounding the floating gate. The memories operated under these mechanisms thus are vulnerable to manufacturing and reliability problems.

In light of the foregoing problems, it is an object of the present invention to provide an insulating barrier in a conductor-insulator system that can be operated to enhance carrier injection efficiency and to reduce operation voltages. It is another object of the present invention to provide charge carriers (electrons or holes) transporting with tight energy distribution and high injection efficiency.

There is a need to further improve memory cells, arrays and logic and to further improve methods of arranging them, for increased cell pitches, cell densities and performance enhancement.

Other objects of the inventions and further understanding on the objects will be realized by referencing to the specifications and drawings.

### SUMMARY

Embodiments of the present invention include a memory device, a memory array and a method of arranging memory devices and arrays. The memory device includes a memory region including a plurality of memory cells, each memory cell with a source, a drain and a channel between the source and the drain, a channel dielectric, a charge storage region and an electrically alterable conductor-material system in proximity to the charge storage region. The memory device includes a plurality of conductor lines. The memory includes a non-memory region having embedded logic including a plurality of transistors, each transistor for electrically coupling one of the conductor lines and each transistor including a transistor source, a transistor drain and a transistor gate.

In one embodiment, the charge storage regions of a plurality of memory cells are substantially in alignment with the transistor gate of one of the transistors.

In one embodiment of the memory device, the conductor lines include first and second cell lines connecting respectively to sources and drains of a first group of memory cells, where for a first one of the transistors, the transistor source is located substantially in alignment with one of the first and second cell lines and the transistor drain is located substantially in alignment with another one of the first and second cell lines.

In one embodiment of the memory device, a plurality of transistors are connected where for the plurality of transistors the drain of one transistor is connected to the source of an adjacent transistor.

In one embodiment of the memory device, the conductor lines include a plurality of first cell lines wherein the charge storage regions are substantially aligned between pairs of the first cell lines.

In one embodiment of the memory device, the plurality of conductor lines includes one or more first cell lines extending to the non-memory region where one or more of the first cell lines electrically couples the embedded logic without an intermediary element or with a conductive intermediary element where the conductive intermediary element is selected from the group consisting of contacts, diffusions, metal lines and transistors or combinations thereof.

In one embodiment of the memory device, the conductor lines include a plurality of first cell lines where the charge storage regions are substantially aligned between pairs of the first cell lines, a plurality of second cell lines for electrically coupling to the charge storage regions of a plurality of memory cells.

The foregoing and other objects, features and advantages of the invention will be apparent from the following detailed description in conjunction with the drawings.

### BRIEF DESCRIPTION OF THE DRAWINGS

FIG. 1A depicts a cross-sectional view of a cell structure to be arranged in accordance with one embodiment of the present specification.

FIG. 1B depicts a schematic representation of the cell of FIG. 1A.

FIG. 2A depicts a cross-sectional view of another cell structure to be arranged in accordance with another embodiment of the present specification.

FIG. 2B depicts a cross-sectional view of an additional cell structure to be arranged in accordance with another embodiment of the present specification.

FIG. 2C depicts a cross-sectional view of a still additional cell structure to be arranged in accordance with another embodiment of the present specification.

FIG. 3 depicts a schematic diagram showing the array architecture for memory cells of the FIG. 2A type arranged in a memory cell region.

FIG. 4A depicts a schematic diagram of a of a memory device having a memory region formed of cells of the FIG. 1A type and of embedded logic in non-memory regions.

FIG. 4B depicts a schematic diagram of a memory device having a memory region formed of cells of the FIG. 1A type and of non-memory regions including a non-memory region having aligned embedded logic.

FIG. 5 depicts a schematic diagram of a of a memory device having a memory region formed of cells of the FIG. 2A type and of non-memory regions including a non-memory region having aligned embedded logic.

FIG. 6 depicts a schematic diagram of a memory device having a memory region formed of cells of the FIG. 1A type and of non-memory regions.

FIG. 7 depicts a top plan view and FIG. 7A depicts a cross-sectional side view of a semiconductor substrate used as the starting structure for the present specification.

FIG. 8 and FIG. 8A represent elements and steps in connection with arranging a Charge Storage Region (“CSR”).

FIG. 9, FIG. 9A, FIG. 9B, FIG. 9D, FIG. 9E and FIG. 9F represent elements and steps in connection with further arranging of the Charge Storage Region (“CSR”).

FIG. 10, FIG. 10A, FIG. 10B, FIG. 10C, FIG. 10D, FIG. 10E and FIG. 10F represent elements and steps in connection with arranging conductor lines, word lines and bit lines.

FIG. 11, FIG. 11A, FIG. 11B, FIG. 11C, FIG. 11D FIG. 11E and FIG. 11F represent elements and steps in connection with arranging the Charge Storage Region (“CSR”).

FIG. 12, FIG. 12A, FIG. 12B, FIG. 12C, FIG. 12D, FIG. 12E and FIG. 12F represent elements and steps in connection with arranging oxides in trenches adjacent memory cell elements and arranging the word lines.

FIG. 13, FIG. 13A, FIG. 13B, FIG. 13C, FIG. 13D, FIG. 13E and FIG. 13F represent elements and steps in connection with arranging multilevel dielectrics for filters and other elements.

FIG. 14A, FIG. 14B, FIG. 14C, FIG. 14D, FIG. 14E and FIG. 14F represent elements and steps in connection with arranging a Self-Aligned-Contact (SAC) etching-stop layer.

FIG. 15A, FIG. 15B, FIG. 15C, FIG. 15D, FIG. 15E, FIG. 15F and FIG. 15G represent elements and steps in connection with arranging embedded CMOS logic.

FIG. 16A, FIG. 16B, FIG. 16C, FIG. 16D, FIG. 16E, FIG. 16F and FIG. 16G represent elements and steps in connection with further arranging embedded CMOS logic.

FIG. 17A, FIG. 17B, FIG. 17C, FIG. 17D, FIG. 17E, FIG. 17F and FIG. 17G represent elements and steps in connection with arranging Tunneling-gate (“TG”) lines.

FIG. 18, FIG. 18A, FIG. 18B, FIG. 18C, FIG. 18D, FIG. 18E, FIG. 18F and FIG. 18G represent elements and steps in connection with arranging salicide regions and other elements.

FIG. 19, FIG. 19A, FIG. 19B, FIG. 19C, FIG. 19D, FIG. 19E and FIG. 19F represent elements and steps in connection with arranging a nitride layer and other elements.

FIG. 20, FIG. 20A, FIG. 20B, FIG. 20C, FIG. 20D, FIG. 20E, FIG. 20F and FIG. 20G represent elements and steps in connection with forming contact holes and other elements.

FIG. 21, FIG. 21A, FIG. 21B, FIG. 21C, FIG. 21D, FIG. 21E and FIG. 21F represent elements and steps in connection with junctions.

FIG. 22, FIG. 22A, FIG. 22C, and FIG. 22G represent elements and steps in connection with processing borderless contacts.

### DETAILED DESCRIPTION

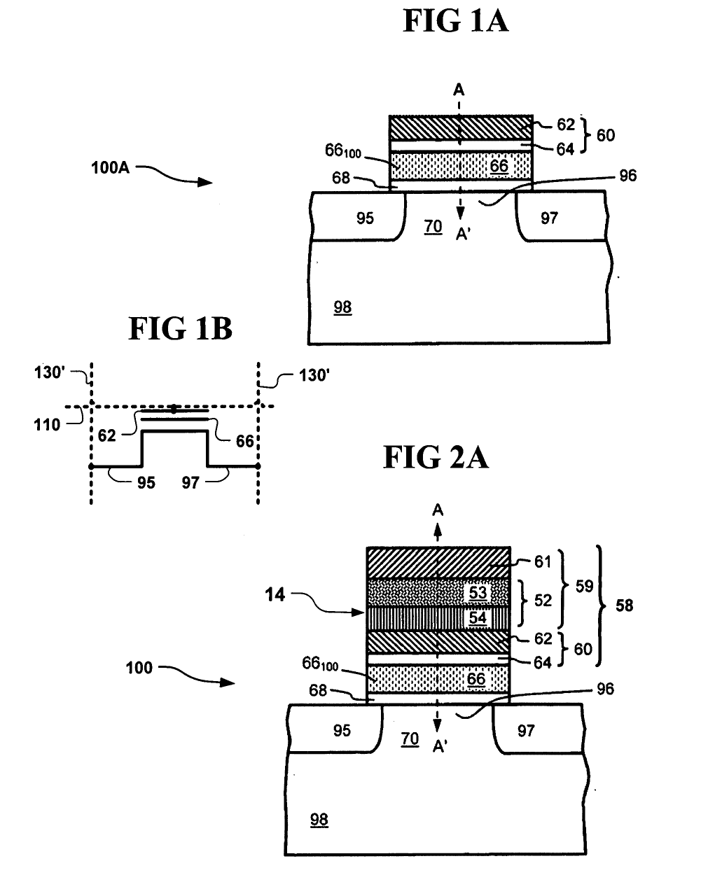

In FIG. 1A, a cross-sectional view of one embodiment of a cell structure including a memory cell 100A to be arranged in accordance with embodiments of the present specification is shown.

In this specification including the claims, different layers, regions, materials and other elements are described as deposited, etched, implanted, formed or otherwise arranged and such descriptions are intended to include all different manners of arranging such elements.

Referring to cell 100A of FIG. 1A, there is shown a charge storage region (“CSR”) 66. The charge storage region 66 includes a floating gate (“FG”) 66₁₀₀, and a channel dielectric (“CD”) 68. A conductor-insulator system 60 comprises a ballistic gate (“BG”) 62 and a retention dielectric (“RD”) 64 as the conductor and insulator of the system, respectively. The BG 62 is disposed adjacent to and insulated from the FG 66₁₀₀ by the retention dielectric (RD 64). The FG 66₁₀₀ is disposed adjacent to and insulated from the body 70 by CD 68. The FG 66₁₀₀ is typically encapsulated and insulated by dielectrics such as RD 64, CD 68, or other dielectrics in close proximity having proper thickness and good insulation property to retain charges thereon without leaking. Typically, RD 64 and CD 68 have the thicknesses in the range from about 5 nm to about 20 nm.

Cell 100A of FIG. 1A further provides a source 95, a channel 96, a drain 97, and a body 70 in a semiconductor substrate 98 (such as a silicon substrate or a silicon-on-insulator substrate). The body 70 comprises a semiconductor material of a first conductivity type (e.g. p-type) having doping level in the range from about 1×10¹⁵ atoms/cm³ to about 1×10¹⁸ atoms/cm³. The source 95 and drain 97 are arranged in the body 70 with the channel 96 of the body defined there between, and are typically heavily doped by impurity of a second conductivity type (e.g. n-type) having doping level in the range of about 1×10¹⁸ atoms/cm³ to about 5×10²¹ atoms/cm³. These doping regions may be arranged by thermal diffusion or by ion implantation. In this specification, the source 95 and drain 97 regions are interchangeable and hence any reference to a “source” can be interchanged with reference to a “drain” and vice versa. Because of this interchangeability, a source or a drain region is referred to as a source/drain region, a drain/source region, a first region or a second region.

The channel dielectric 68 is somewhat longer than the channel 96 so as to project over end portions of the source 95 and the drain 97.

In FIG. 1A, the FG 66₁₀₀ is for collecting and storing charge carriers and is polysilicon, poly SiGe or any other types of semiconductor materials that can effectively store charges. The conductivity of FG 66₁₀₀ is an n-type or a p-type. Materials for BG 62 is from the group comprising a semiconductor, such as n+ polysilicon, p+ polysilicon, heavily-doped poly SiGe etc, or a metal, such as aluminum (Al), platinum (Pt), Au, Tungsten (W), Molybdenum (Mo), ruthenium (Ru), tantalum (Ta), nickel (Ni), tantalum nitride (TaN), titanium nitride (TiN) etc, or alloy thereof, such as tungsten-silicide, nickel-silicide etc. While BG in cell 100A is shown in a single layer, BG 62 may comprise more than one layer. The thickness of BG 62 is in the range from about 20 nm to about 200 nm.

FIG. 1B depicts a schematic representation of the cell 100A of FIG. 1A. Where used in this specification, the FIG. 1B schematic represents cells of the cell 100A type.

The architecture of the cell 100A of FIG. 1A is described in the above identified cross-referenced application US 2006/0001053. The cross-referenced application discloses memory cells and arrays of the cell 100A type and further arranged using electrically alterable conductor-material systems. For purposes of the present specification including the claims, an electrically alterable conductor-material system is a system or element including a conductor having charge carriers with an energy distribution and including a material having an interface with the conductor with potential barriers in proximity to the interface where the potential barriers are electrically alterable to control transport of the charge carriers.

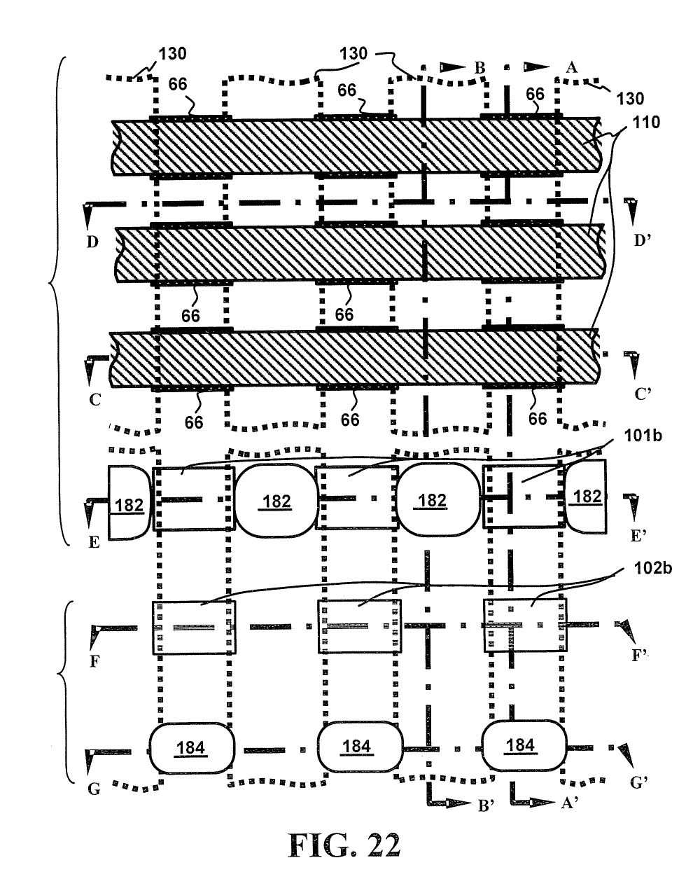

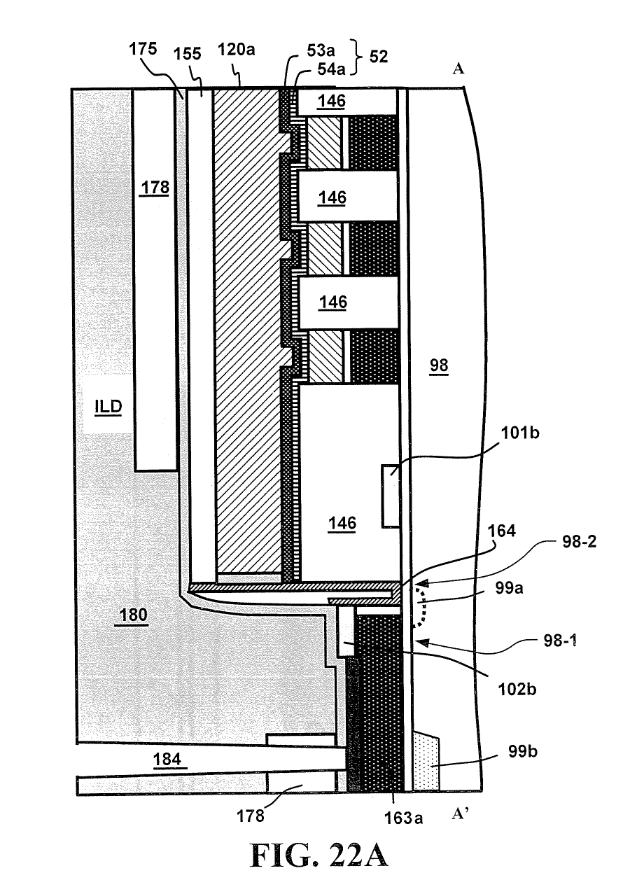

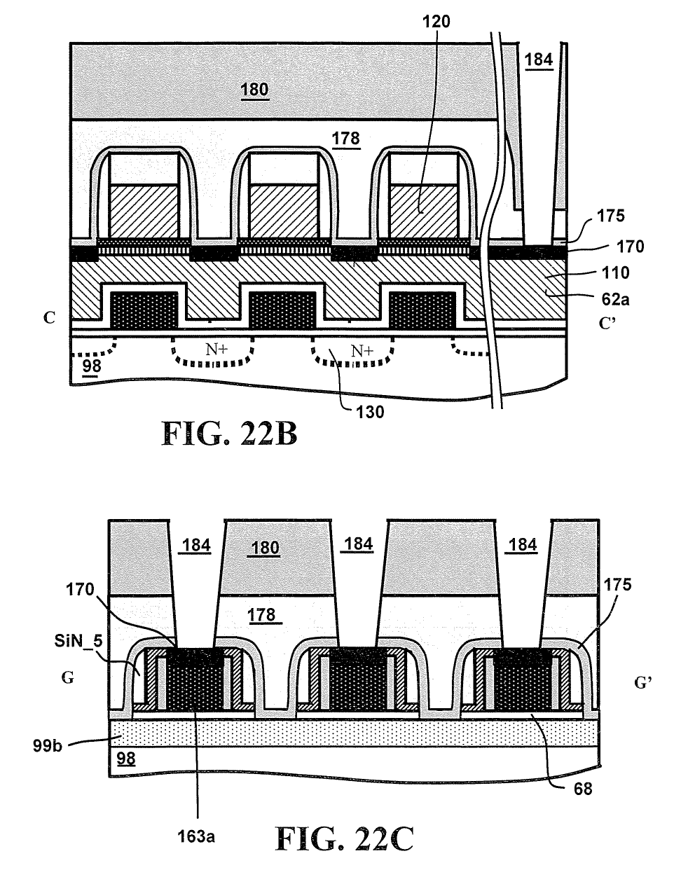

In the cross-referenced application US 2006/0001053, the conductor-material systems include a conductor-filter system, referring to FIG. 22 therein, arranged with a conductor that supplies thermal charge carriers with a filter contacting the conductor. The filter includes dielectrics for providing a filtering function on the charge carriers of one polarity, wherein the filter includes electrically alterable potential barriers for controlling flow of the charge carriers of one polarity through the filter in one direction. In addition to controlling the one polarity of charge carriers, the filter further includes another set of electrically alterable potential barriers for controlling the flow of charge carriers of an opposite polarity through the filter in another direction that is substantially opposite to the one direction.

In the cross-referenced application US 2006/0001053, the conductor-material systems include a conductor-insulator system comprising a conductor having energized charge carriers with an energy distribution and an insulator contacting the conductor at an interface. The insulator has an Image-Force potential barrier adjacent to the interface where the Image-Force potential barrier is electrically alterable to permit the energized charge carriers to transport there over.

In the cross-referenced application US 2006/0001053, the conductor-material systems include a charge-injection system comprising a conductor-filter system having a conductor for supplying thermal charge carriers and a filter contacting the conductor and including dielectrics for providing a filtering function on the charge carriers. The filter includes one set of electrically alterable potential barriers for controlling flow of the charge carriers of one polarity through the filter in one direction, and further includes another set of electrically alterable potential barriers for controlling flow of charge carriers of an opposite polarity through the filter in another direction that is substantially opposite to the one direction. The charge-injection system further comprises a conductor-insulator system. The conductor-insulator system includes a second conductor contacting the filter and having energized charge carriers from the filter, and an insulator contacting the second conductor at an interface and having an Image-Force potential barrier adjacent to the interface. The Image-Force potential barrier is electrically alterable to permit the energized charge carriers transporting there over.

The foregoing conductor-material systems used in memory cells are arranged in arrays in first and second directions with spaces between cells in each direction, that is, the cells have first direction and second direction cell pitches (P). In order to increase the cell density, it is desirable that the cell pitches be made small. Historically, the industry has tended over time to reduce the cell pitches for memory cells and arrays. Each of the cells in an array has interconnecting cell lines arranged in at least first and second directions such that cell lines cross over in the array. The naming of cell lines (word lines, tunneling lines, bit lines or other lines) and the number of the first lines and of the second lines in any particular direction are a matter of design convenience and, in general, the names, numbers and directions may be selected to satisfy any particular architecture desired.

Frequently, memory devices include related circuits including timing, sensing and logic (generally referred to as “embedded logic”) on the same substrate and it is desirable that the elements and steps for arranging the memory cells also be used for arranging the related logic and other embedded logic. References to logic in this specification, including the claims, also are referred to as logic transistors, embedded logic, logic circuits, Logic CMOS and other non-memory cell terms. In general, “logic” and “embedded logic” refers to components and methods relating to logical functions and other functions distinguished from components and methods relating to the memory functions of memory cells.

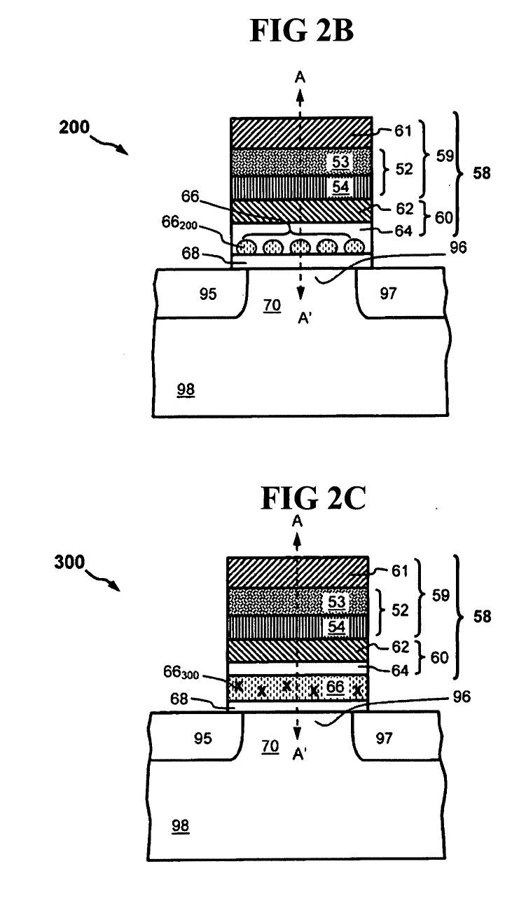

FIG. 2A depicts a cross-sectional view of one embodiment of a cell structure including a memory cell 100 to be arranged in accordance with embodiments of the present specification. Memory cells, like the cell 100, include one or more electrically alterable conductor-material systems 58 to control the transport of carriers. For purposes of the present specification including the claims, an electrically alterable conductor-material system is a system (that is, a group of elements) including a conductor having charge carriers with an energy distribution and including a material having an interface with the conductor with potential barriers in proximity to the interface where the potential barriers are electrically alterable to control transport of the charge carriers.

In this specification including the claims, different layers, regions, materials and other elements are described as deposited, etched, implanted, formed or otherwise arranged and such descriptions are intended to include all different manners of arranging such elements.

FIG. 2A shows a cross-sectional view of a cell 100 in accordance with one embodiment of the cross-referenced application US 2006/0001053. Referring to cell 100 of FIG. 2A, there is shown an electrically alterable system 58 including a conductor-filter system 59 and a conductor-insulator system 60. The system 58 is in proximity to the charge storage region (“CSR”) 66. The charge storage region 66 includes a floating gate (“FG”) 66₁₀₀, and a channel dielectric (“CD”) 68. FIG. 2A depicts the system 58 symmetrically aligned with the charge storage region 66. Such alignment, however, is only illustrative since the system 58 need only be in proximity to the charge storage region 66 such that transport of the charge carriers can be controlled.

The conductor-filter system 59 comprises a tunneling-gate (“TG”) 61, and a filter 52, wherein TG 61 corresponds to the conductor of the system 59. The filter 52 provides the band-pass filtering function, the charge-filtering function, the voltage divider function, and the mass-filtering function. In one embodiment, the filter 52 comprises a tunneling dielectric (“TD”) 53 and a blocking dielectric (“BD”) 54. The conductor-insulator system 60 comprises a ballistic gate (“BG”) 62 and a retention dielectric (“RD”) 64 as the conductor and insulator of the system, respectively. The cell structure in regions from TG 61 to RD 64 is constructed by “contacting” the filter 52 of the conductor-filter system 59 to the conductor (BG 62) of the conductor-insulator system 60. The structure thus arranged has TD 53 sandwiched in between the TG 61 and the BD 54 regions, and has BD 54 sandwiched in between the TD 53 and the BG 62 regions. The BG 62 is disposed adjacent to and insulated from the FG 66₁₀₀ by the retention dielectric (RD 64). The FG 66₁₀₀ is disposed adjacent to and insulated from the body 70 by CD 68. The FG 66₁₀₀ is typically encapsulated and insulated by dielectrics such as RD 64, CD 68, or other dielectrics in close proximity having proper thickness and good insulation property to retain charges thereon without leaking. Typically, RD 64 and CD 68 have the thicknesses in the range from about 5 nm to about 20 nm. TD 53 and BD 54 can comprise dielectrics having a uniform chemical element or a graded composition on its element. TD 53 and BD 54 is dielectric materials from the group comprising oxide, nitride, oxynitride, aluminum oxide (“A₂O₃”), hafnium oxide (“HfO₂”), zirconium oxide (“ZrO₂”), tantalum pen-oxide (“Ta₂O₅^{”)}. Furthermore, any composition of those materials and the alloys formed thereof, such as hafnium oxide-oxide alloy (“HfO₂—SiO₂”), hafnium-aluminum-oxide alloy (“HfAlO”), hafnium-oxynitride alloy (“HfSiON”) etc. is used as dielectric materials for TD and BD. In the embodiment, an oxide dielectric having thickness from 2 nm to 4 nm and a nitride dielectric having thickness ranging from about 2 nm to 5 nm are chosen for TD 53 and BD 54, respectively.

Cell 100 of FIG. 2A further provides a source 95, a channel 96, a drain 97, and a body 70 in a semiconductor substrate 98 (such as a silicon substrate or a silicon-on-insulator substrate). The body 70 comprises a semiconductor material of a first conductivity type (e.g. p-type) having doping level in the range from about 1×10¹⁵ atoms/cm³ to about 1×10¹⁸ atoms/cm³. The source 95 and drain 97 are arranged in the body 70 with the channel 96 of the body defined there between, and are typically heavily doped by impurity of a second conductivity type (e.g. n-type) having doping level in the range of about 1×10¹⁸ atoms/cm³ to about 5×10²¹ atoms/cm³. These doping regions may be arranged by thermal diffusion or by ion implantation. In this specification, the source 95 and drain 97 regions are interchangeable and hence, in general, any reference to a “source” can be interchanged with reference to a “drain” and vice versa.

The channel dielectric 68 is somewhat longer than the channel 96 so as to project over end portions of the source 95 and the drain 97.

In FIG. 2A, the TG 61 is shown overlapping the BG 62 to form an overlap portion between the two, where at least a portion of FG 66₁₀₀ is disposed there under. The overlap portion is essential in the cell structure as supplied charge carriers are filtered through that portion in order to be transported through BG 62, RD 64 and finally into the FG 66₁₀₀. The FG 66₁₀₀ is for collecting and storing such charge carriers and is polysilicon, poly SiGe or any other types of semiconductor materials that can effectively store charges. The conductivity of FG 66₁₀₀ is an n-type or a p-type. Materials for TG 61 and BG 62 is from the group comprising a semiconductor, such as n+ polysilicon, p+ polysilicon, heavily-doped poly SiGe etc, or a metal, such as aluminum (Al), platinum (Pt), Au, Tungsten (W), Molybdenum (Mo), ruthenium (Ru), tantalum (Ta), nickel (Ni), tantalum nitride (TaN), titanium nitride (TiN) etc, or alloy thereof, such as tungsten-silicide, nickel-silicide etc. While TG and BG in cell 100 are shown each in a single layer, BG 62 and TG 61 may comprise more than one layer in their respective architecture. For example, TG 61 can comprise a nickel-silicide layer arranged atop of a polysilicon layer to form a composite layer for TG 61. The thickness of TG 61 is in the range from about 80 nm to about 500 nm, and the thickness of BG 62 is in the range from about 20 nm to about 200 nm.

The program operation of memory cell 100 is done by employing the ballistic-electron injection mechanism or the piezo-ballistic-electron injection mechanism. These injection mechanisms inject energized charge carriers having energy distribution with an energy spectrum in the range of about 30 meV to about 300 meV onto CSR 66. For the specific embodiment, voltage of TG 61 is chosen in the range of about −3.3 V to about −4.5 V relative to voltage of BG 62 to form a voltage drop therebetween for injecting electrons having tight energy distribution. This is done, for example, by applying a −3.3 V voltage to TG 61 and a 0 V voltage to BG 62 to generate the −3.3 V voltage drop across TG and BG. Alternately, it is done by applying other voltage combinations, such as −1.8 V to TG and +1.5 V to BG. The voltage drop across TG and BG is further lowered by lowering the Image-Force barrier height of the conductor-insulator system 60. This is done by coupling a voltage in the range of about 1 V to about 3 V to CSR 66 through applying voltages in the range of about 1 V to about 3.3 V to source 95, drain 97, and body 70. For example, assuming 8 nm for the thickness of RD, such Image-Force lowering effect can reduce the −3.3 V voltage drop across TG and BG to a range of about −2.8 V to about −3.0 V.

The FG 66₁₀₀ of CSR 66 is negatively charged with electron carriers after the cell 100 is programmed to a program state. The programmed state of cell 100 is erased by performing an erase operation. The erase operation is done by employing the ballistic-hole injection mechanism or the piezo-ballistic-hole injection mechanism. These injection mechanisms inject energized charge carriers having energy distribution with an energy spectrum in the range of about 30 meV to about 300 meV onto CSR 66. For the specific embodiment, voltage of TG 61 is chosen in the range of about +5 V to about +6 V relative to voltage of BG 62 to form a voltage drop there between for injecting light-holes having tight energy distribution. This is done, for example, by applying a +3 V voltage to TG 61 and a −2 V voltage to BG 62 to generate the +5 V voltage drop across TG and BG. Alternately, it is done by applying other voltage combinations, such as +2.5 V to TG and −2.5 V to BG. The voltage drop across TG and BG is further lowered by lowering the Image-Force barrier height of the conductor-insulator system 60. The Image-Force barrier is somewhat lowered by FG 66₁₀₀ when it is negatively charged, and is generally further lowered by coupling a voltage in the range of about −1 V to about −3 V to CSR 66 through applying voltages in the range of about −1 V to about −3.3 V to source 95, drain 97, and body 70. For example, assuming 8 nm for the thickness of RD, such Image-Force lowering effect can reduce the +5 V voltage drop across TG and BG to a range of about +4.5 V to about +4.7 V.

Finally, to read the memory cell, a read voltage of approximately +1 V is applied to its drain 97 and approximately +2.5 V (depending upon the power supply voltage of the device) is applied to its BG 62. Other regions (i.e. source 95 and body 70) are at ground potential. If the FG 66₁₀₀ is positively charged (i.e. CSR 66 is discharged of electrons), then the channel 96 is turned on. Thus, an electrical current will flow from the source 95 to the drain 97. For an single-bit per cell storage scheme, the current thus read along with the bias thus applied would be the “1” state. On the other hand, if the FG 66₁₀₀ is negatively charged, the channel 96 is either weakly turned on or is entirely shut off. Even when BG 62 and drain 97 are raised to the read voltage, little or no current will flow through channel 96. In this case, either the current is very small compared to that of the “1” state or there is no current at all. In this manner, the memory cell is sensed to be programmed at the “0” state. Such read method is for illustration purpose and can be readily modified to other storage schemes such as multi-bits per cell scheme, wherein more than one bit is stored in one single cell.

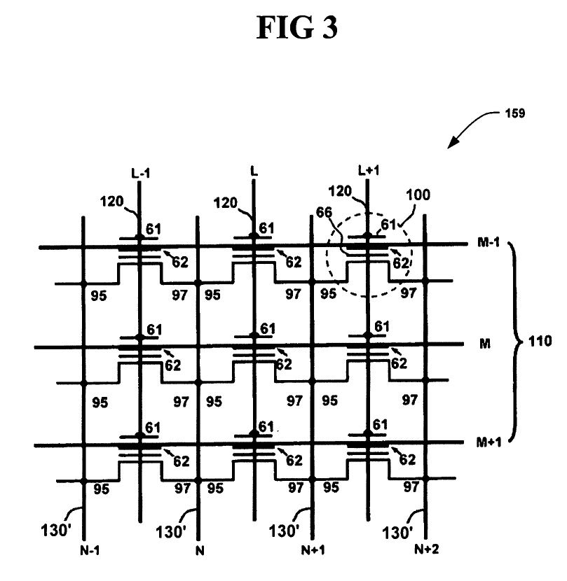

The memory cell 100 is illustrated in storing charges on CSR 66 of a conductive or semiconductor material (i.e. FG 66₁₀₀) that is electrically insulated from but capacitively coupled to surrounding conductive regions. In such a storage scheme, charges are evenly distributed through out CSR 66. However, it should be apparent to those of ordinary skill in the art that this disclosure is not limited to the particular embodiments illustrated herein and described above, but can encompass any other type of schemes for storing charges. For example, memory cells can store charges in CSR comprising a plurality of discrete storage sites such as nano-particles or traps in a dielectric layer, as illustrated in FIGS. 2 and 3, respectively.

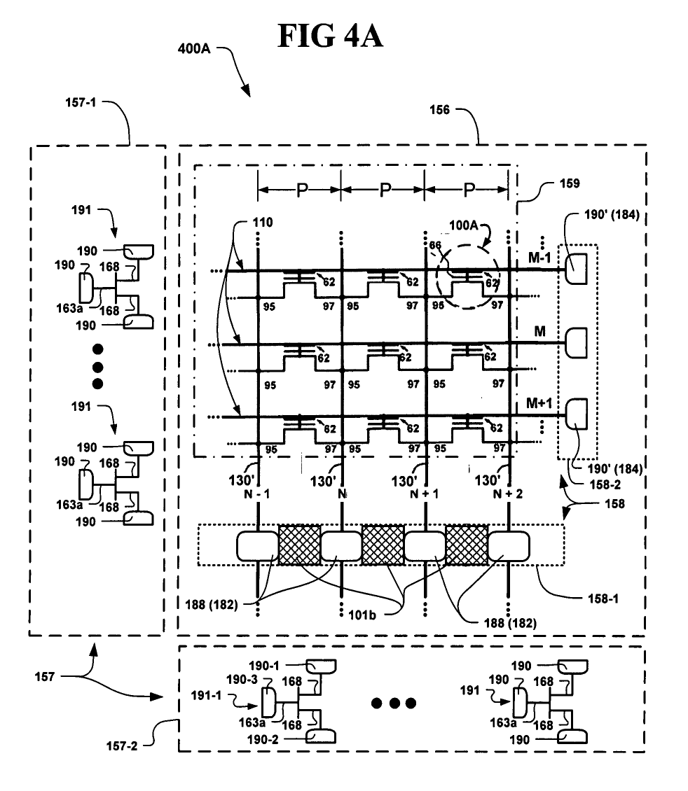

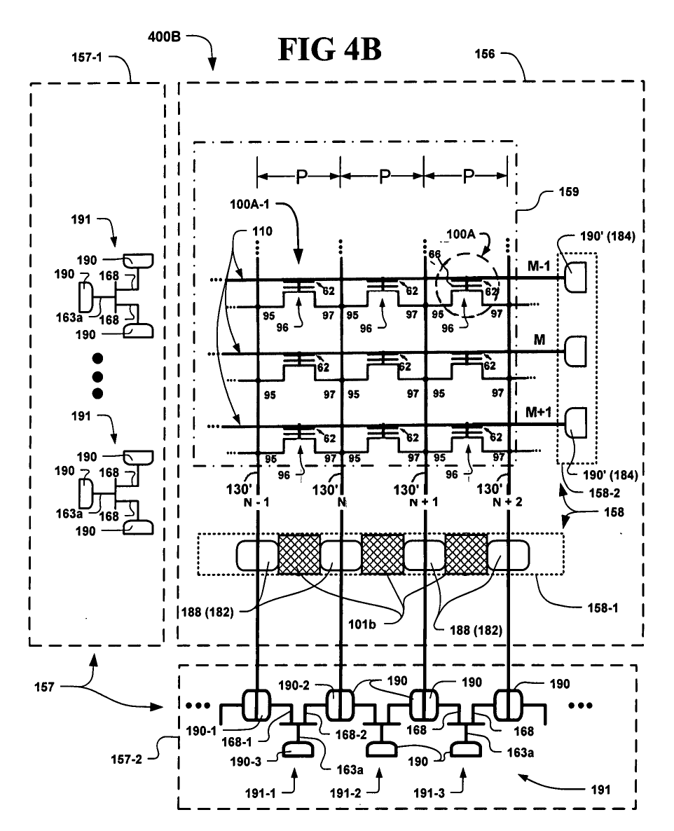

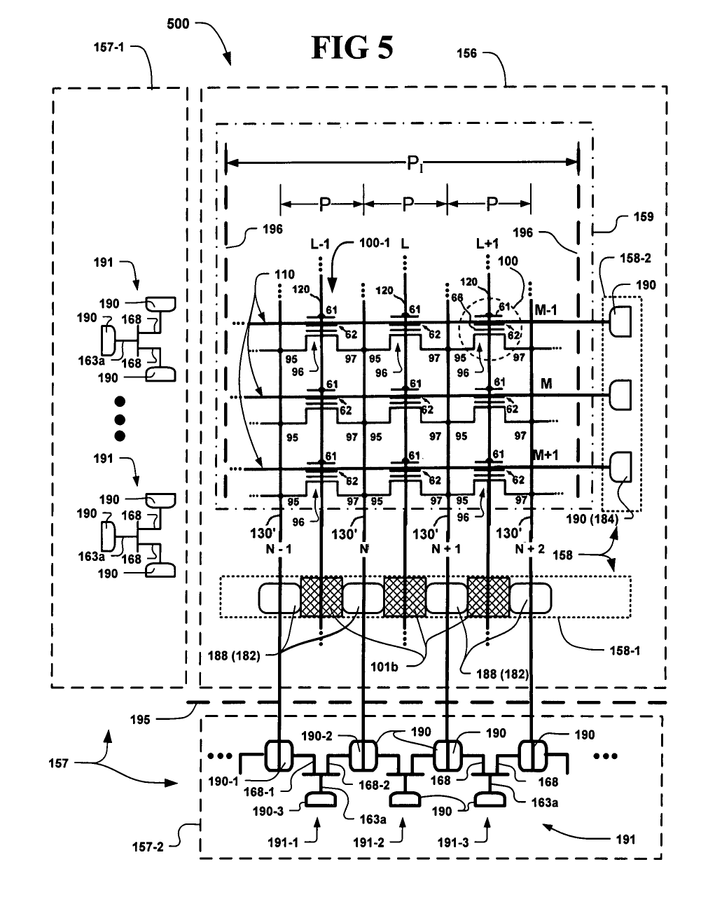

In FIG. 2A, the memory cell 100 is typical for use in a memory region (see FIG. 4 and FIG. 5) where each memory cell is to be arranged on a common substrate and wherein, for each memory cell, the source, the drain and the channel extend to a surface of the substrate, wherein the channel dielectric is adjacent the surface at the channel and wherein the charge storage region and electrically alterable conductor-material system are stacked in proximity to the channel dielectric.

FIG. 2B depicts a cross-sectional view of a memory cell 200 to be arranged in accordance with another embodiment employing nano-particles. In FIG. 2B, the cell 200 is a variation of the cell 100 of FIG. 2A.

The cell 200 is like cell 100 of FIG. 2A except that instead of a conductive region of FG 66₁₀₀ as CSR 66, the memory cell 200 is provided with a plurality of spaced-apart nano-particles 66₂₀₀ formed in nanometer scale as CSR 66. The nano-particles 66₂₀₀ are typically in an oval shape having a dimension in the range of about 2 nm to about 10 nm, and are shown contacting CD 68 and arranged in RD 64. The RD 64 is shown in a single layer and is a layer of a stack of different dielectrics, such as a layer of oxide/nitride/oxide stack. The nano-particles as the storage sites are silicon nano-crystals each in an oval shape having a diameter in the range of about 2 nm to about 7 nm, and are arranged by using well-known CVD techniques. The nano-particles is other types of semiconductor materials (e.g. Ge, SiGe alloy etc.), dielectric particles (e.g. HfO₂), or metals (e.g. Au, Ag, Pt etc.) that are in nano-particles form and can effectively store charges.

It should understood that the nano-particles 66₂₀₀ need not be in an oval shape in their cross section, need not be co-planar with the substrate surface, but rather is at any level under or above the substrate surface, and with other shapes that can effectively store charge carriers. Moreover, the nano-particles 66₂₀₀ need not be contacting the RD 64, need not be fully in the RD 64, but rather can be partially in RD 64 and partially in CD 68, or fully in CD 68.

FIG. 2C depicts a cross-sectional view of a memory cell 300 to be arranged in accordance with another embodiment employing traps in a dielectric layer. The cell 300 is like memory cell 100 of FIG. 2A except that instead of a conductive region for CSR 66, the cell 300 provides a CSR 66 of trapping dielectric having a plurality of trapping centers (traps 66₃₀₀). The dielectric CSR 66 uses traps 66₃₀₀ as the charge storage sites and is a nitride layer arranged, for example, by using LPCVD (Low-Pressure-Chemical-Vapor-Deposition) techniques well-known in the art. Other dielectrics such as HfO₂ and ZrO₂ having traps of a deeper trapping energy can also be used as material for the trapping dielectric.

Both memory cells 200 and 300 in FIG. 2B and FIG. 2C utilize schemes storing charges in localized charge storage sites that are in the form of nano-particles 66₂₀₀ and traps 66₃₀₀, respectively. These cells are operated in a similar way as that illustrated for cell 100 in connection with FIG. 2A. The advantages of the cell 200 and cell 300 structures are reduced process complexity, and a negligible interference between adjacent cells when such cells are arranged in a memory array. Furthermore, in the event there is a local breakdown in surrounding insulators of one of the sites, charges stored at other sites can still be retained to preserve logic data stored thereon.

The dimensions of the cells are closely related to the design rules of a given generation of process technology. Therefore, the dimensions on cells and on regions defined therein are only illustrative examples. In general, however, the dimension of the memory cells must be such that supplied charges are filtered and transported through the filter at a higher absolute voltage between TG and BG (e.g. 3 V to 6 V) and blocked by the filter at a lower absolute voltage (e.g. 2.5 V or lower). Furthermore, the dimensions of the BG and RD must be such that a large portion of filtered charges are allowed to transport through that region and be collected by the CSR at an injection efficiency typically ranging from about 10⁻⁶ to about 10⁻¹.

It is to be understood that the embodiments illustrated herein and described above are only by way of example and other variations may be employed.

FIG. 3 depicts a schematic diagram showing a memory cell region 159. The memory cells, where memory cell 100 of FIG. 2A is typical, are arranged in an array architecture in the memory cell region 159.

The memory cells of FIG. 3 are typically arranged in a rectangular array of rows and columns, wherein a plurality of cells are constructed in NOR or NAND logical function architecture well-known in the art. FIG. 3 illustrates a NOR array architecture in schematic diagram with illustration made using the memory cell 100 of FIG. 2A. Of course, other cells such as cell 200 of FIG. 2B and cell 300 of FIG. 2C can be employed and other logical function architectures can be employed.

Referring to FIG. 3, there are shown conductor lines in the form of first cell lines 110 (for example, word lines), oriented in a first direction (for example, row direction). In the example described, the first cell lines 110 include lines M−1, M, and M+1. Further, there are shown conductor lines in the form of second cell lines (for example, tunneling lines and bit lines) oriented in a second direction (for example, column direction). In the example described, the second cell lines include tunneling lines 120, namely tunneling lines L−1, L, and L+1, and include bit-lines 130′, namely N−1, N, N+1, and N+2.

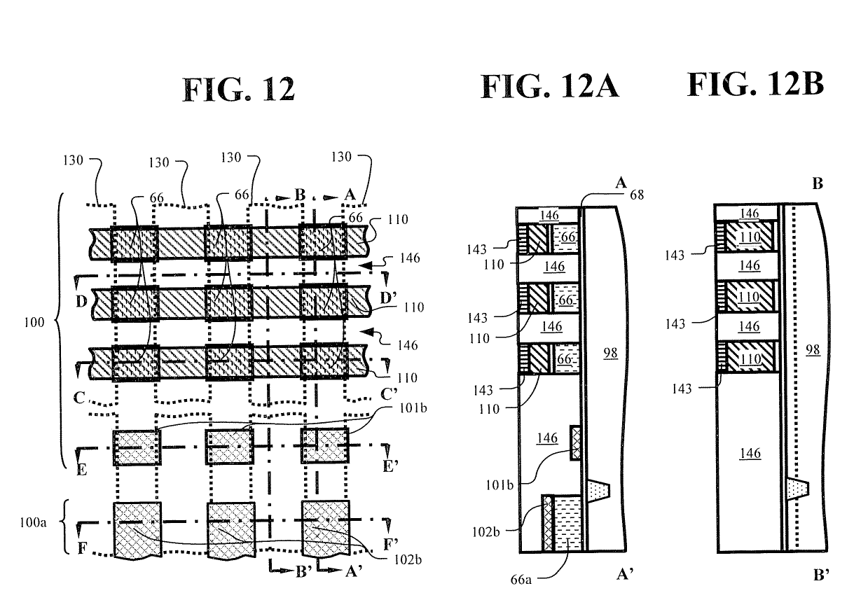

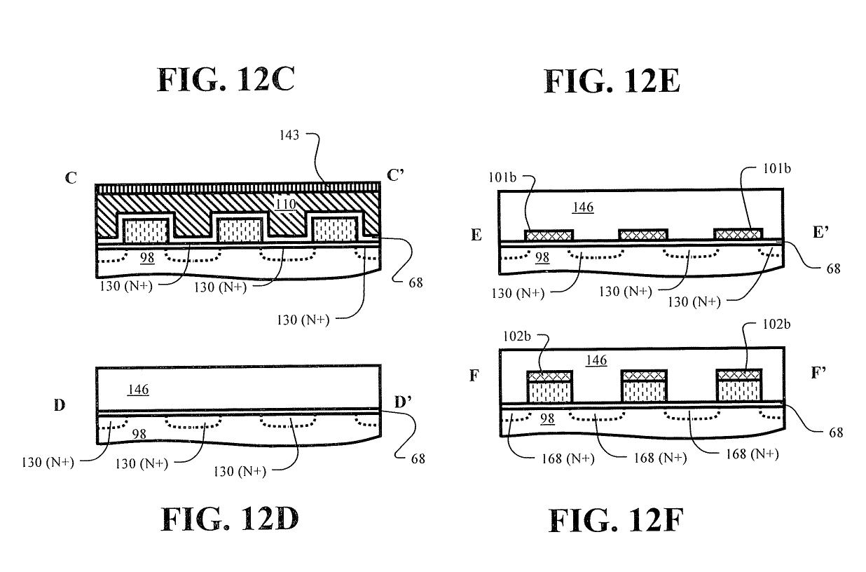

The naming of conductor lines cell lines (word lines, tunneling lines, bit lines or other lines) and the numbers of the first lines and of the second lines in any particular direction are a matter of design convenience and, in general, the names, numbers and directions can be selected to satisfy any particular architecture desired. Also, the conductor lines in a memory device are also present in the non-memory regions of a memory device. Frequently, the conductor lines for embedded logic are short and form the source or drain of a transistor (see source drain regions 168 in FIG. 12F hereinafter for example).

A ballistic gate (“BG”) 62 of each of the memory cells 100 in the same row are electrically coupled by one of the first lines 110. Thereby, the line M+1 connects BG 62 of each of the memory cells in the lowermost row. Each of the tunneling lines 120 connects all the TG 61 of memory cells in the same column. Thereby, the tunneling-line L−1 connects TG 61 of each of the memory cells in the leftmost column of FIG. 3. Likewise, each of the bit-lines 130′ connects all the drains 97 of memory cells in the same column. Thereby, the bit-line N connects the drain 97 of each of the memory cells in the leftmost column of FIG. 3. Since the array demonstrated in this example uses a virtual ground array architecture, the bit-line N for memory cells on the leftmost column also functioned as the source-line N for memory cells of an adjacent column (i.e. the center column of FIG. 3). Those of skill in the art will recognize that the term source and drain may be interchanged, and the source-lines and drain-lines or source-lines and bit-lines may be interchanged. Further, the word-line is electrically coupled to BG 62 of the memory cell. Thus, the term BG line may also be used interchangeably with the term word-line.

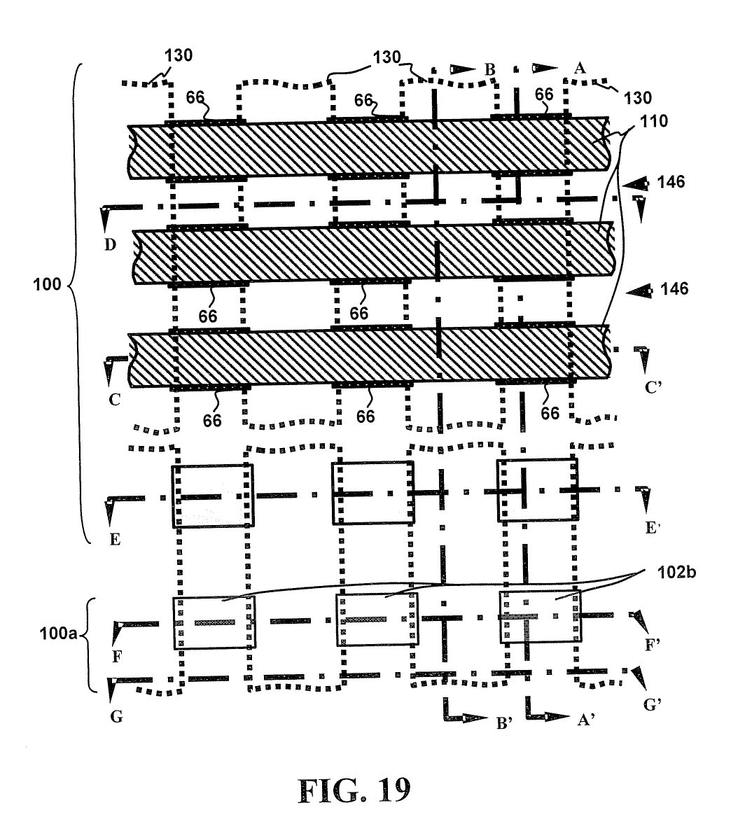

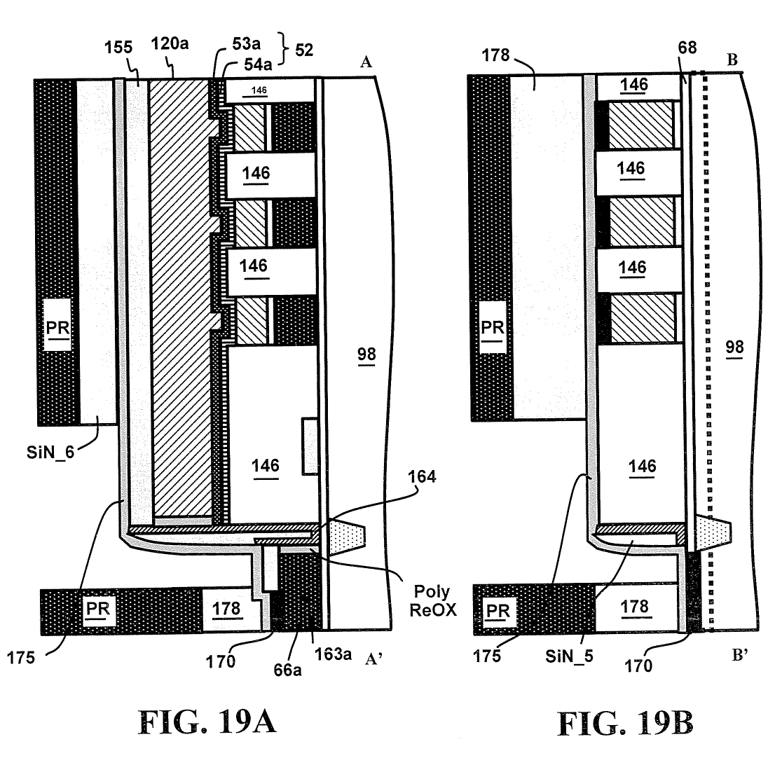

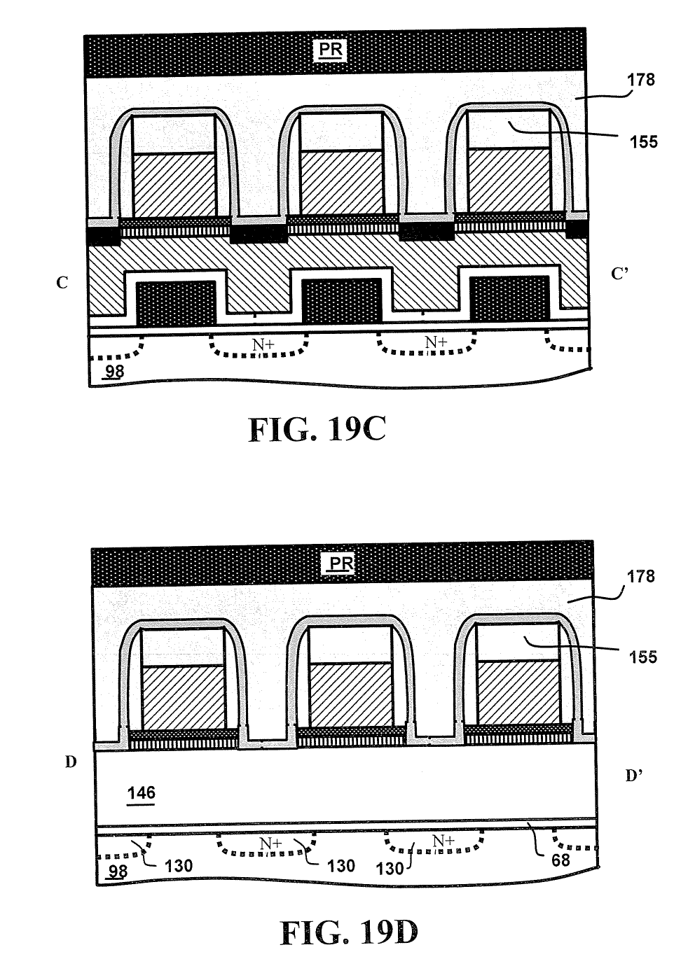

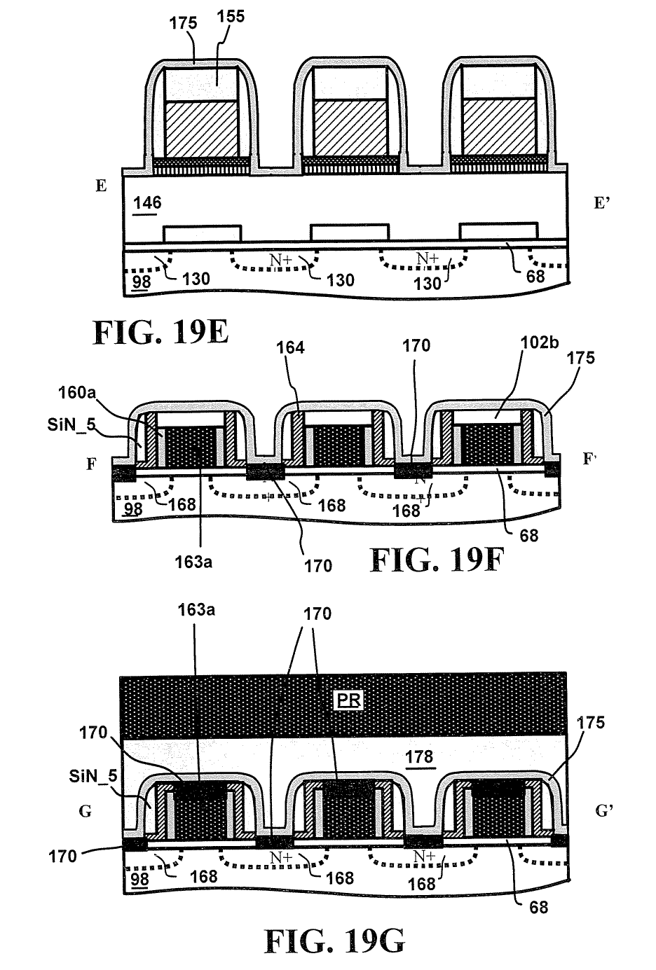

The cell lines 110, 120 and 130′ are formed using different processes. For example, the cell lines 130′ (bit-lines) are formed in one embodiment as a diffusion (see diffusion 130 in FIG. 19, for example), in other embodiments as a metal line or in additional embodiments can be both diffusion and metal lines as long as the diffusion and metal lines electrically couple the sources of the memory cells in the same column. For another example, the cell lines 110 (word lines) are formed in one embodiment as a poly, in other embodiments as metal lines or in additional embodiments can be both poly and metal lines as long as the poly and metal lines electrically couple the ballistic gates of the memory cells in the same rows. For an additional example, the cell lines 120 (tunneling lines) are formed in one embodiment as a poly, in other embodiments as metal lines or in additional embodiments can be both poly and metal lines as long as the poly and metal lines electrically couple the tunneling-gates of the memory cells in the same columns.

The NOR array shown in FIG. 3 is a well-known array architecture used as an example to illustrate the array formation using memory cells of the present specification. It should be appreciated that while only a small segment of an array is shown, the example in FIG. 3 illustrates any size of array of such regions. Additionally, the memory cells of the present embodiments are applied to other types of NOR array architectures. For example, while each of the bit lines 130′ is arranged to share with cells on an adjacent column as a source line, a memory array is arranged with cells on each column having their own dedicated source line. Furthermore, although the present specification is illustrated in a single cell and in a NOR array, it should be apparent to those of ordinary skill in the art that a plurality of cells of the present specification is arranged in a rectangular array of rows and columns, wherein the plurality of cells are constructed in NAND array architecture well-known in the art or a combination of a NAND and a NOR array structure.

For the memory cells described, it should be noted that both program and erase operations are performed with absolute bias at a level less than or equal to 3.3V. Furthermore, the erase mechanism and cell architecture enable the individually erasable cells feature, which is ideal for storing data such as constants that require periodic change. The same feature is further extendable to small groups of such cells which are erased simultaneously (e.g. cells storing a digital word, which typically contains 8 cells). Additionally, the same feature is also further extendable to such cells which are erasable simultaneously in large groups (e.g. cells storing code for software programs, which typically can contain 2048 cells configured in a page, or can contain a plurality of pages in block or array architectures).

In FIG. 4A, the memory device 400A is shown in schematic detail. The memory device 400A includes the memory region 156 that is further formed of the memory cell region 159 and the connection region 158 adjacent the memory cell region 159. The memory device 400A also includes the non-memory regions 157, including regions 157-1 and 157-2, adjacent the memory region 156. The memory device 400A is typically formed on a semiconductor substrate (see 98 in FIG. 1A). The cell 400A, as shown in FIG. 1A, is typical of the cells in the memory array 400A. The memory device 400A is shown for purposes of representation to include three rows and three columns of cells 100A. Of course, arrays are typically larger and typically include rows and columns with 4, 8, 16, 32, 64, 128, 256, 512 and generally 2^{N} rows or columns of cells where N is any integer. The number of rows need not equal the number of columns.

The density of the cells and the pitch (P) of the cells 100A and cell lines (110 and 130′) in the memory cell region 159 in FIG. 4A is in part controlled by the ability to make connections or otherwise electrically couple to the plurality of cell lines (110 and 130′) in the connection region 158 without requiring greater dimensions for the connections than are required for the other parts of the cells. The term “electrically couple” means to form a relationship between elements that are situated and configured such that an electrical voltage, current, field or other electrical phenomena is coupled between the elements. Electrical coupling occurs when elements such as first cell lines 130′ (bit-lines) and embedded logic 191 are coupled without an intermediary element (that is with direct contacting) or with a conductive intermediary element. The conductive intermediary element is selected from the group consisting of contacts (for example, contacts 188), diffusions (for example, diffusions 130 in FIG. 19), metal lines (such as metal lines described in connection with FIG. 25) and transistors (for example, transistors 191-1, 191-2, 191-3, . . . or transistors 193-1, 193-2, 193-3, 193-4, . . . of FIG. 4B) and combinations thereof.

In FIG. 4A, the connection region 158 is part of the memory region 156 and is adjacent the memory cell region 159. The connection region 158, including connection regions 158-1 and 158-2, is used for connection to any cell lines such as the cell lines 110, 120 and 130′. For example, the connection region 158-1 includes contacts 188, shown schematically electrically coupled to the lines 130′. The contacts 188 are formed in holes 182 between pairs of insulators 101b. The insulators 101b are typically arranged concurrently with the cell elements of the cells in the memory cell region 159 and hence are readily aligned substantially in alignment with the cell lines 130′. In a typical embodiment the self-aligned contact contacts (SAC) 188 are formed in holes 182 using self-aligned contact (SAC) elements and steps. Accordingly, the pitch (P) of the contacts 188 in certain embodiments matches the pitch (P) of the cells in the memory region 156 and similarly, the contact insulators 101b while offset from the cell lines 130′ are arrayed substantially in alignment with the cell lines 130′. Elements that are spaced apart with a repeating separation are defined as having the pitch (P) and are defined to be “arrayed at the cell pitch”. Accordingly, in FIG. 4A, the cells 100A, the cell lines 130′, the holes 182, the contacts 188 and the contact insulators 101b are all arrayed at the cell pitch. Also, the contact holes 182 are arranged substantially in alignment with the cell lines 130′.

The cell lines (110, 120,130) have been shown for simplicity as straight lines, but in general, cell lines can be rounded, bent, turned, staggered, zigzagged or otherwise arrayed in a repeating pattern where the “pitch” is some dimension related to the repetition of the pattern.

In the FIG. 4A device 400A, the contact insulators 101b are one or more materials selected from the group consisting of oxide, nitride, oxynitride and alloys thereof.

The term “self-aligned” means contacts and contact holes that extend through layers of a semiconductor device with an arrangement of the materials and layers of the semiconductor device such that the holes and contacts are preferentially constrained to alignment at desired locations. For example, in the device 400A of FIG. 4A, the contacts 188 and holes 182 are “self-aligned” because the contacts 188 are formed in the holes 182 between pairs of insulators 101b where the insulators 101b, formed for example by nitride material, tend to constrain the holes 182 (and hence the contacts 188 in the holes 182) in the desired aligned location between the insulators 101b and thereby to be substantially aligned with the cell lines 130′.

In FIG. 4A, the cell lines 130′ are first cell lines (bit-lines) that in one embodiment extend into the connection region 158-1 and electrically couple the contacts 188. In an alternate embodiment, the cell lines 130′ terminate prior to and do not extend into the connection region 158-1. In such alternate embodiment, a transistor or other electrically coupling means (such as transistors 193 in FIG. 4B) has one terminal electrically coupled to the cell line 130′ and another terminal electrically coupled in the connection region 158-1, for example to a contact 188, whereby the cell line 130′ is electrically coupled into the connection region 158-1 without extending into the connection region 158-1.

The contacts 188 are formed substantially between pairs of the contact insulators 101b. The contacts 188 need not be symmetrically located with respect to the contact insulators 101b. A contact 188 may be closer to or offset from a particular one of the pair of contact insulators 101b relative to the other one of the pair of contact insulators 101b. Nonetheless, the locations of the contact insulators 101b is deemed to be substantially in alignment with the cell lines 130′ even though offsets are or may be present.

The connection region 158-2 includes contacts 190′, shown schematically to be electrically coupled to the M−1, M and M+1 lines 110 which are typical of many such cell lines when greater numbers of rows of memory cells are present. The contacts 190 in some embodiments are formed using borderless contact elements and steps and are typically used in locations where the dimensions are not as critical as for the self-aligned contacts 188.

The term “borderless” means contacts and contact holes that extend through layers of a semiconductor device where the arrangement of the materials and layers of the semiconductor device do not preferentially constrain the location contact holes and the contacts. For example, in the device 400A of FIG. 4A, the contacts 190′ and holes 184 are “borderless” because the arrangement of the materials and layers of the semiconductor device are such that the holes and contacts are not preferentially constrained.

In the FIG. 4A device 400A, a plurality of contacts 188, 190 and 190′ and contact holes 188 and 184 are employed wherein the contacts are selected from the group consisting of self-aligned contacts (188), borderless contacts (190) and combinations thereof.

FIG. 4A is schematic and the actual shape of the contacts 188 and 190 can be rectangular, round or any other shape, regular or irregular.

In FIG. 4A, the non-memory regions 157 are adjacent the memory region 156. The non-memory regions 157 include non-memory elements such as timing circuits, sense amplifiers and many other types of circuits. The transistors 191 (also identified as connection elements 191) are shown as representative examples and include contacts 190 at the gate 163a and the source and/or drain 168. In the FIG. 4A example, the transistors 191 are at locations that are generally independent of the array layout of the cells in the memory region 156. Typically, the contacts 190 are formed using borderless contact elements and steps that do not have as high a resolution as the contacts 188 formed using the self-aligned contact (SAC) elements and steps.

In FIG. 4A, the non-memory regions 157 include embedded logic 191 including a plurality of transistors, each transistor having three terminals 168. The terminals 168 include, for example, a first terminal that is a source, a second terminal that is a drain and third terminal that is a gate. Each of the terminals 168 is electrically coupled to a contact 190. The transistors of the embedded logic 191 are connected in many different ways. For example, transistors have one or more terminals electrically coupled to one or more cell lines and have one or more terminals electrically coupled to the terminals of other transistors of embedded logic 191. In FIG. 4A, at least one transistor terminal 168 in the non-memory region is electrically coupled to a first cell line 130′. In FIG. 4A, the embedded logic 191 in non-memory region 157-2 includes one or more transistors each having transistor terminals 168 wherein at least one of the transistor terminals is electrically coupled to at least one of the cell lines 130′. The cell lines 130′ are diffusions (for example, diffusions 130 in FIG. 19) or metal lines (such as metal lines described in connection with FIG. 25). For such electrical coupling, one or more of the first cell lines 130′ (for example, N−1 cell line 130′) extends (not shown in FIG. 4A, see FIG. 4B) into the non-memory region 157-2 and, by way of example, electrically couples to a contact 190-1 for a transistor 191-1.

The memory device of 400A of FIG. 4A includes another connection region 158-2 including another plurality of contacts 190′ (in holes 184) wherein one or more of the plurality of cell lines (110,130′) of memory device 400A extend into the connection region 158-2 for electrically coupling to one or more of the another plurality of contacts 190′. For example, the M−1, M and M+1 cell lines 110 extend into the region 158-2.

In FIG. 4B, the memory device 400B is shown in schematic detail. The memory device 400B is like the memory device 4A and includes the memory region 156 that is further formed of the memory cell region 159 and the connection region 158, including connection regions 158-1, 158-2 and 158-3 adjacent the memory cell region 159. The memory device 400B also includes the non-memory regions 157, including regions 157-1 and 157-2, adjacent the memory region 156. The memory device 400B is typically formed on a semiconductor substrate (see 98 in FIG. 1A). The cell 100A, as schematically shown in FIG. 1B, is typical of the cells in the memory array 400A. The memory device 400B is shown for purposes of representation to include three rows and three columns of cells 100A. Of course, arrays are typically larger and typically include rows and columns with 4, 8, 16, 32, 64, 128, 256, 512 and generally 2^{N} rows or columns of cells where N is any integer. The number of rows need not equal the number of columns.

In FIG. 4B, a plurality of cell lines 110 and 130′ includes first cell lines 130′ extending into the connection region 158-1, wherein the connection region 158-1 includes a plurality of contact insulators 101b, each of the contact insulators aligned substantially between pairs of the first cell lines (for example, between the pair N−1 and N, the pair N and N+1 and the pair N+1 and N+2), and wherein each of the contacts 188 is arranged substantially between pairs of the contact insulators. In FIG. 4B, the contact region contacts 188 are arrayed at the cell pitch (P) in the contact region 158-1 and one or more of the contacts 188 electrically couples to one or more of the first cell lines 130′. Electrical coupling of contacts 188 to more than one cell line 130′ occurs, for example, in the non-memory region 157-2 by the transistors 191-1, 191-2, 191-3 and so on. Also, the connection region 158-3 includes transistors 193 (for example, 193-1, 193-2, 193-3 and 194-4, . . . ), typically arrayed at the cell pitch, P. The transistors 193 are source/drain inline with the cell lines 130′. Each transistor 193 includes terminals connected respectively to a source. a drain and a gate whereby when the gate is enabled, the source/drain electrically couples the cell line 130′ to the non-memory region 157. For example, the transistor 193-1 couples to one of the cell lines, the N−1 cell line 130′, and the transistor 193-2 couples to another one of the cell lines, the N cell line 130′.

In FIG. 4B, the cell lines 130′ are first cell lines (bit-lines) that in one embodiment extend into the connection region 158-1 and electrically couple the contacts 188. In an alternate embodiment, the cell lines 130′ terminate prior to and do not extend into the connection region 158-1. In such alternate embodiment, a transistor or other electrically coupling means has one terminal electrically coupled to the a cell line 130′ and another terminal electrically coupled in the contact region 158-1, for example to a contact 188, whereby the cell line 130′ is electrically coupled into the connection region 158-1 without extending into the connection region 158-1.

In the memory device of FIG. 4B, the non-memory region 157-2 has, from the plurality of cell lines 110 and 130′, an extension of first cell lines 130′ wherein the non-memory region includes a plurality of non-memory region contacts (for example, contacts 190-1 and 190-2) each non-memory region contact connecting to one of the first cell lines 130′ (for example, 190-1 connecting to N−1 line 130′ and 190-2 connecting to N cell line 130′). In FIG. 4B, the non-memory region 157-2 includes embedded logic, for example, including a plurality of transistors 191. In FIG. 4B, the non-memory region 157-2 has embedded logic 191 and the plurality of cell lines (110, 130′) of memory device 400B includes one or more first cell lines 130′ extending into the non-memory region 157-2 for electrically coupling the embedded logic 191.

In FIG. 4B, the transistors 191 each have three terminals 168. The terminals 168 include, for example, a first terminal that is a source, a second terminal that is a drain and third terminal that is a gate. Each of the terminals 168 is electrically coupled to a contact 190. In particular, each transistor having a first terminal, for example a source 168-1 electrically coupled to a first cell line (for example, N−1 line 130′ electrically coupled to source 168-1 by contact 190-1), a second terminal, for example a drain connected to a first cell line (for example, N line 130′ electrically coupled to drain 168-2 by contact 190-2) and a gate connected to a non-memory region contact (for example, gate 163a electrically coupled to contact 190-3).

In FIG. 4B, elements in the non-memory region 157-2 are spaced apart with a repeating separation defined as the pitch (P) and hence, like elements in the memory region 159, are defined to be “arrayed at the cell pitch”. In FIG. 4B, the elements arrayed at the cell pitch include cells 100A, the cell lines 130′, the holes 182, the contacts 188, the contact insulators 101b, the non-memory contacts 190 and the transistors 191.

The memory device of 400B of FIG. 4B includes another connection region 158-2 including another plurality of contacts 190′ (in holes 184) wherein one or more of the plurality of cell lines (110,130′) of memory device 400B extend into the connection region 158-2 for electrically coupling to one or more of the another plurality of contacts 190′. For example, the M−1, M and M+1 cell lines 110 extend into the region 158-2 for electrically coupling to one or more of the another plurality of contacts 190′.

The memory device 400B of FIG. 4B includes, for one or more incidences, a first one of the transistors (191-1) having a first-transistor first terminal (168-1) electrically coupled to a first one of the cell lines (N−1), has a first-transistor second terminal (168-2) electrically coupled to a second one of the cell lines (N) and has a first-transistor gate (163a) whereby enabling the first-transistor gate electrically couples the first one of the cell lines (N−1) and the second one of the cell lines (N).

When repeated for a first and second of the one or more incidences, the memory device of 400B of FIG. 4B includes for the first incidence, a first one of the transistors (191-1) having a first-transistor first terminal (168-1) electrically coupled to a first one of the cell lines (N−1), has a first-transistor second terminal (168-2) electrically coupled to a second one of the cell lines (N) and has a first-transistor gate (163a) whereby enabling the first-transistor gate(163a) electrically couples the first one of the cell lines (N−1) and the second one of the cell lines (N). For the second incidence of the one or more incidences, a second one of the transistors (191-2) has a second-transistor first terminal connected to the second one of the cell lines (N), has a second-transistor second terminal connected to a third one of the cell lines (N+1) and has a second-transistor gate whereby enabling the second-transistor gate electrically couples the second one of the cell lines (N) and the third one of the cell lines (N+1).

In FIG. 5, the memory device 500 is shown in schematic detail and is substantially the same as the memory device 400A in FIG. 4A except the cells 100 are typically of the form of cell 100 in FIG. 2A having the additional L−1, L and L+1 cell lines 120. In the non-memory region 157-2 of FIG. 5, the embedded logic 191, including by way of example the transistors 191-1, 191-2 and 191-3 as typical, are arrayed at the cell pitch and are oriented and located according to the array layout of the cells 100 in the memory cell region 159. In particular, considering transistor 191-1 as typical, the contact 190-1 connecting to the first region source/drain terminal 168-1 of transistor 191-1 is aligned with the N−1 line 130′ that couples to first regions (sources 95) of a first column 100A-1 of cells 100A in memory cell region 159. Similarly, the contact 190-2 connecting to the second cell region drain/source 168-2 of transistor 191-1 is aligned with the N line 130′ that couples to second cell regions (drains 97) of the first column 100A-1 of cells 100A. The source 95 cell regions and the drain 97 cell regions are of course interchangeable and hence the first cell region in cells 100A may be either source or drain and the second cell regions may be either source or drain. The transistor 191-1 has a gate 163a coupled to contact 190-3 whereby transistor 191-1 causes the source-to-drain connection between source/drains 168-1 and 168-2, contacts 190-1 and 190-2 and N−1 line 130′ and N line 130′ to be coupled with a low impedance (short) or a high impedance (open). When the connection transistor 191-1 is controlled to be conducting, transistor 191-1 electrically couples the N−1 cell line 130′ to the N cell line 130′. The electrical coupling can be to any number of other cell lines by operation of the transistors 191-2, 191-3, . . . and so on where any number of additional transistors 191 (not shown) may be provided based upon the size of the memory device 500.

In FIG. 5, the conductor lines (110, 120 and 130′) are formed using different processes. For example, the cell lines 130′ (bit-lines) are formed in one embodiment as a diffusion and in other embodiments as a metal line. The cell lines in general may extend from the memory cell region 159 into a connection region 158 and/or into a non-memory region 157. Typically, the cell lines 130′ are bit-lines that extend at least into the connection region 158.

In FIG. 5, the cell lines 130′ are first cell lines (bit-lines) that in one embodiment extend into the connection region 158-1 and electrically couple the contacts 188. In an alternate embodiment, the cell lines 130′ terminate prior to and do not extend into the connection region 158-1. In such alternate embodiment, a transistor or other electrically coupling means has one terminal electrically coupled to the a cell line 130′ and another terminal electrically coupled in the contact region 158-1, for example to a contact 188, whereby the cell line 130′ is electrically coupled into the connection region 158-1 without extending into the connection region 158-1.

In FIG. 5, the non-memory region 157-2 in FIG. 5 includes embedded logic 191 including a plurality of transistors 191 where each transistor (for example, transistor 191-1) is electrically coupled between a first contact (190-1) and a second contact (190-2) electrically coupled to first (N−1 line 130′) and second (N cell line 130′) cell lines 130′, respectively, whereby the transistor 191-1 electrically couples the contact 190-1 and first cell line (N−1 cell line 130′) to the contact 190-2 and second cell line (N cell line 130′). It still further apparent from the foregoing description that the memory device of FIG. 5 includes two or more transistors (for example, transistors 191-1 and 191-2) for electrically coupling three or more cell lines (for example, N−1, N and N+1 cell lines 130′). With this layout, the transistors embedded logic 191 has the transistors 191-1, 191-2 191-3, and so on, arrayed at the cell pitch (P).

It is apparent from FIG. 5, that a plurality of cell lines 110 and 130′ includes first cell lines 130′ extending into the connection region 158-1, wherein the connection region 158-1 includes a plurality of contact insulators 101b, each of the contact insulators aligned substantially between pairs of the first cell lines (for example, between the pair N−1 and N, the pair N and N+1 and the pair N+1 and N+2), and wherein each of the contacts 188 is arranged substantially between pairs of the contact insulators. In FIG. 5, the non-memory region contacts 188 are arrayed at the cell pitch (P) in the non-memory region 157-2 and one or more of the non-memory region contacts 188 is electrically coupling to one or more of the cell lines 130′. Electrical coupling of a contact such as contact 190-1 to more than one cell line 130′ occurs by enabling the transistors 191-1, 191-2, 191-3 and so on to be conducting. As described, the non-memory region 157-2 is an example of embedded logic including a plurality of transistors 191, including transistors 191-1, 191-2 and 191-3, where each transistor 191 has a transistor terminal 168 electrically coupled to at least one of the cell lines 130′.

FIG. 5, the memory device 500 is shown in schematic detail. The memory device 500 includes the memory region 156 that is further formed of the memory cell region 159 and the connection region 158 adjacent the memory cell region 159. The memory device 500 also includes the non-memory regions 157, including regions 157-1 and 157-2, adjacent the memory region 156. The memory device 500 is typically formed on a semiconductor substrate (see 98 in FIG. 2A). The cells 100 in FIG. 5 include all the elements of the cell 100 in FIG. 2A. The cells 100 in FIG. 5, therefore, differ from the cells 100A in FIG. 4A and in FIG. 4B in that the cells 100 additionally include, referring to FIG. 2A, a Conductor Filter system 59 including a Blocking Dielectric (“BD”) 54 and a Tunneling Dielectric (“TD”) 53 and a Tunneling-gate (“TG”) 61. Only the tunneling-gates 61 are shown explicitly in FIG. 5. The tunneling-gates 61 in FIG. 5 are electrically coupled in columns by the cell lines 120 where the L−1 cell line 120 for the column 100-1 is typical.

In FIG. 5, the memory device 500 in some embodiments employs a suitable isolation 195, such as a LOCOS (LOCal Oxidation of Silicon) isolation, a shallow-trench isolation (STI), a junction isolation or combinations thereof well-known in the art, to define and isolate memory region 156 from the non-memory region 157. In some embodiments, isolation is not used in the memory region 156. In other embodiments, suitable isolation 196, such as LOCOS isolation or shallow-trench isolation (STI), is employed in the memory region 156. Typically, when isolation 196 is employed, the isolation 196 is not employed for every cell line (bit line) 130′. The memory device includes one or more isolations 195 and 196 located in the memory device between the memory and non-memory regions, between the memory cell region and the connection region or in any of the memory cell, connection or non-memory regions. The isolations 195 and 196 employ any suitable isolation scheme, such as LOCOS isolation or shallow-trench isolation (STI). In one embodiment, the cell lines 130′ are bit lines occurring at a bit-line pitch (P). Additionally, isolations 196 are located in the memory cell region 159 and extending in the direction of the cell lines 130′. In FIG. 5, the isolations 196 occur at an isolation pitch (PI) where the isolation pitch (PI) is greater than the bit-line pitch (P) so that there is not an isolation 196 for each bit line 130′. Isolation may occur in the bit cell line direction (such as isolations 196 in FIG. 5), in the word cell line direction (such as isolation 195 in FIG. 5). For any isolations, the pitch and the regions in which the isolations are located are all optional and are included, not included or varied as to location and pitch as may be warranted by particular embodiments and design needs. Although the isolations are shown in the memory device 500 of FIG. 5, the isolations similarly can be used in the arrays for the memory devices 400A and 400B of FIG. 4A and FIG. 4B.

The memory device of 500 of FIG. 5 includes another connection region 158-2 including another plurality of contacts 190′ (in holes 184) wherein one or more of the plurality of cell lines (110,130′) of memory device 500 extend into the connection region 158-2 for electrically coupling to one or more of the another plurality of contacts 190′. For example, the M−1, M and M+1 cell lines 110 extend into the region 158-2 for electrically coupling to one or more of the another plurality of contacts 190′.

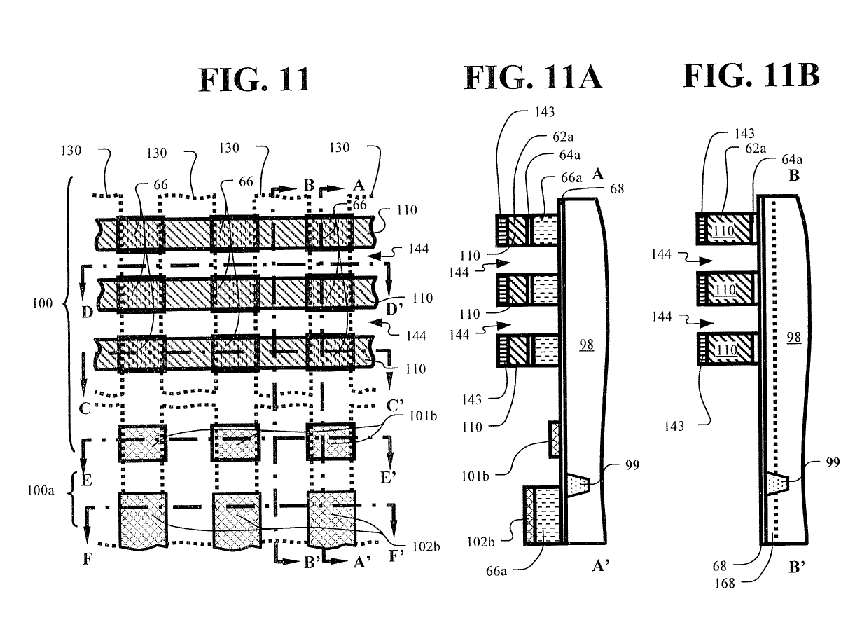

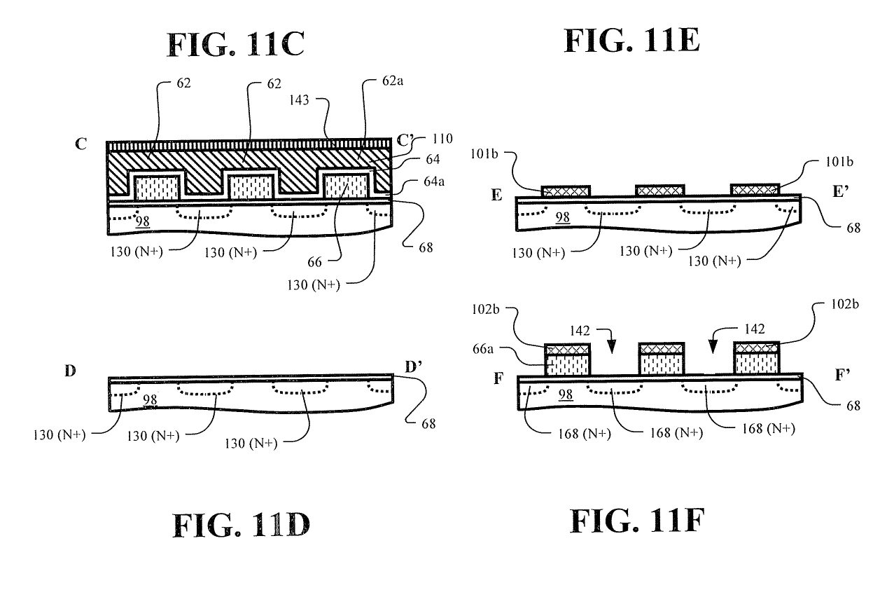

In FIG. 4A, FIG. 4B and/or FIG. 5, the terminals (for example, 168-1, 168-2) for a transistor (for example, transistor 191-1) connect in one embodiment described through contacts (for example, 190-1, 190-2) to cell lines (for example, N−1 line 130′ and N line 130′). In other embodiments, the terminals (for example, 168-1, 168-2) for a transistor (for example, 191-1) connect directly to cell lines (for example, N−1 line 130′ and N line 130′) by sharing the same diffusions without need for contacts (for example, 190-1, 190-2). The diffusion of the cell lines 130′ are described in connection with FIG. 11 and the diffusion of the terminals 168 are described in connection with FIG. 27F. These diffusions when extended into a common region directly connect the terminals (for example, 168-1, 168-2) for a transistor (for example, 191-1) directly to cell lines (for example, N−1 line 130′ and N line 130′) without need for any contacts.

The terminology and numbering in the present specification is substantially the same as in the cross-referenced application US 2006/0001053 and that application is hereby incorporated by reference for definitions and examples of terms similarly used in the present specification.

In particular, the present application and the cross-referenced application US 2006/0001053 include the following like-numbered elements in a cell, a Substrate (“SUB”) 98 having a Source (“S”) 95, Drain (“D”) 97, a Channel (“C”) 96, a body (B) 70, a Channel Dielectric (“CD”) 68, a Charge Storage region (“CSR”) 66, a Conductor-Insulator system 60 including a Retention Dielectric (“RD”) 64 and a Ballistic Gate (“BG”) 62, a Conductor Filter system 59 including a Blocking Dielectric (“BD”) 54, a Tunneling Dielectric (“TD”) 53 and a Tunneling-gate (“TG”) 61.

In a general sense, the memory device 100 (and analogously other memory devices such as memory devices 200 and 300 of FIG. 2B and FIG. 2C) is a semiconductor device comprising a first conductive region (61), a dielectric region (52), a second conductive region (62) disposed adjacent to and insulated from the first conductive region by the dielectric region, a third region (66) disposed adjacent to and insulated from the second conductive region, and a strain source (178) providing a mechanical stress to at least one of the first and the second conductive regions.

Of those common like-numbered elements, the Conductor Filter system 59 including the Blocking Dielectric (“BD”) 54 and the Tunneling Dielectric (“TD”) 53 and the Tunneling-gate (“TG”) 61 are added elements to the cell 100A of FIG. 1A to form the cell 100 of FIG. 2A. As described in the cross-referenced application US 2006/0001053, the Blocking Dielectric (“BD”) 54 preferably has an energy band gap narrower than that of Tunneling Dielectric (“TD”) 53. Further, Blocking Dielectric (“BD”) 54 preferably has a larger dielectric constant relative to that of Tunneling Dielectric (“TD”) 53, among other reasons, to reduce the electric field and enhance the blocking effect on electrons and to permit a larger portion of the applied voltage to appear across Tunneling Dielectric (“TD”) 53.

In a general sense, the memory device 100 (and analogously other memory devices such as memory devices 200 and 300 of FIG. 2B and FIG. 2C) is a semiconductor device comprising a first conductive region (61), a dielectric region (52), a second conductive region (62) disposed adjacent to and insulated from the first conductive region by the dielectric region, a third region (66) disposed adjacent to and insulated from the second conductive region, and a strain source (178) providing a mechanical stress to at least one of the first and the second conductive regions.

In an embodiment, the dielectric region includes a charge injection filter (52) disposed in between the first and the second conductive regions, wherein the charge injection filter permits transporting of charge carriers of one polarity type from the first conductive region through the second conductive region to the third region and blocks transporting of charge carriers of an opposite polarity type from the second conductive region to the first conductive region.

In an embodiment, the mechanical stress introduced by the strain source (178) is a tensile stress or a compressive stress. In an embodiment, the mechanical stress produces a strain along a direction substantially parallel to a direction of charge carriers transported in the second conductive region.

In an embodiment, the second conductive region comprises material selected from the group consisting of Pt, Au, W, Mo, Ru, Ta, TaN, TiN, silicide, n+ polysilicon, p+ polysilicon, n+ poly SiGe, porous silicon, and p+ poly SiGe.

In an embodiment, the strain source (178) comprises material selected from the group consisting of nitride, tungsten-silicide, amorphous silicon, poly SiGe, TaN, and TiN.

In an embodiment, the strain source (178) comprises dislocation loops in at least one of the first and the second conductive regions.

In an embodiment, the charge injection filter comprises a first dielectric (54) disposed adjacent to the second conductive region and a second dielectric (53) disposed adjacent to the first conductive region and wherein the first dielectric has an energy band gap narrower than an energy band gap of the second dielectric.

In an embodiment, a product of a dielectric constant of the first dielectric and a thickness of the second dielectric is greater than a product of a dielectric constant of the second dielectric and a thickness of the first dielectric.

In an embodiment, the second dielectric comprises oxide, and the first dielectric comprises material selected from the group consisting of nitride, oxynitride, Al₂O₃, HfO₂, TiO₂, ZrO₂, Ta₂O₅, and alloys formed thereof.

In an embodiment, the second dielectric comprises oxynitride, and the first dielectric comprises material selected from the group consisting of nitride, Al₂O₃, HfO₂, TiO₂, ZrO₂, Ta₂O₅, HfO₂—SiO₂, and alloys formed thereof.

In an embodiment, the third region comprises material selected from the group consisting of conductive material, nano-particles, and dielectrics.

In a general sense, the memory device 100 (and analogously other memory devices such as memory devices 200 and 300 of FIG. 2B and FIG. 2C) is a semiconductor device further comprising a first conductive region (61) having charge carriers for ballistic transport, a second conductive region (62) disposed adjacent to and insulated from the first conductive region to control the ballistic transport of the charge carriers, a third region (66) disposed adjacent to and insulated from the second conductive region where the third region receives the charge carriers with an injection efficiency for the ballistic transport, and the strain source (178) generating mechanical stress in at least one of the first and second conductive regions to enhance the injection efficiency of the ballistic transport.

In an embodiment, the mechanical stress is generated by ion implantation where typically the ion implantation comprises implanting a chemical element selected from the group consisting of Ge, Si, As, and nitrogen.

In a general sense, the memory device 100 (and analogously other memory devices such as memory devices 200 and 300 of FIG. 2B and FIG. 2C) is a semiconductor device still further comprising a first conductive region (61) having a population of charge carriers, a second conductive region (62) disposed adjacent to and insulated from the first conductive region for controlling transport of charge carriers from the first conductive region where the charge carriers in the second conductive region have a mean-free-path, a third region (66)) disposed adjacent to and insulated from the second conductive region, the third region for receiving the charge carriers with an injection efficiency, a strain source (178) providing a mechanical stress in at least one of the first and second conductive regions to alter the injection efficiency.

In an embodiment, the population of charge carriers in the first conductive region is altered by the mechanical stress to enhance the injection efficiency.

In an embodiment, the mean-free-path in the second conductive region is increased by the mechanical stress to enhance the injection efficiency.

The density of the cells and the pitch (P) of the cells 100 and the cell lines (110, 120, 130′) in the memory cell region 159 in FIG. 5 is in part controlled by the ability to make connections to the cell lines (110, 120, 130′) in the connection region 158 without requiring greater dimensions for the connections than are required for the other parts of the cells. In FIG. 5, the connection region 158 is part of the memory region 156 and is adjacent the memory cell region 159. The connection region 158-1 includes contacts 188, shown schematically, coupled to the lines 130′. The contacts 188 are formed between pairs of insulators 101b. The insulators 101b are arranged concurrently with the cell elements of the cells in the memory cell region 159 and hence are readily aligned with the cell lines 130′. Accordingly, the pitch of the contacts 188 matches the pitch of the cells in the memory region 156. The connection region 158-2 includes contacts 190, shown schematically, coupled to the lines M−1, M and M+1 which are typical of many such cell lines when greater numbers of rows of memory bit cells are present. The contacts 188 are formed between pairs of the contact insulators 101b. The contacts 188 need not be symmetrically located with respect to the pair of contact insulators 101b or a particular one of the contact insulators. A contact 188 may be closer to or offset from a particular contact insulator 101b than the other. The contacts 188 may have irregular shapes. The insulators 101b are arranged concurrently with the cell elements of the cells in the memory cell region 159 and hence are readily aligned with the cell lines 130′. Accordingly, in the connection region 158-2, each contact 188 is located in proximity to a pair of the contact insulators 101b. While only one contact 188 can be located between a pair of the contact insulators 101b, additional one or more contacts 188 may be located between the same pair of the contact insulators 101b. The contact insulators 101b can be elongated or of different shapes relative to the size and shapes of the contacts 188 to facilitate the presence of multiple contacts 188 between pairs of contact insulators 101b.

FIG. 5 is schematic and the actual shape of the contacts 188 and 190 can be rectangular, round or any other shape, regular or irregular. The important feature is that pairs of the insulators 101b bracket the contacts 188 and hence the contacts 188 from being misaligned with the cell lines 130′. The insulators 101b are formed concurrently with the formation of the cell structures and hence are automatically aligned with the cell lines 130′. In a typical embodiment the contacts 188 are formed in self-aligned contact holes using self-aligned contact (SAC) elements and steps. Accordingly, the pitch of the contacts 188 in such embodiments matches the pitch of the cells in the memory region 156.

The contacts 188 are formed in contact holes 182 between pairs of the contact insulators 101b. The contacts 188 and contact holes 182 need not be symmetrically located with respect to the contact insulators 101b. A contact 188 and a contact hole 182 may be closer to or offset from a particular one of the pair of contact insulators 101b relative to the other one of the pair of contact insulators 101b. The contact holes formed using the self-aligned contact (SAC) steps provide insulators (see 172 in FIG. 24E) adjacent sides of the holes that prevent the contacts from shorting to conductive regions.

The connection region 158-2 includes contacts 190, shown schematically coupled to the lines M−1, M and M+1 which are typical of many such cell lines when greater numbers of rows of memory bit cells are present. The contacts 190 in some embodiments are formed using borderless contact elements and steps and are typically used in locations where the dimensions are not as critical as they are for the self-aligned contacts 188.

In FIG. 5, in non-memory region 157-2, the embedded logic 191, including the cells 191-1, 191-2 and 191-3, are typical examples and are oriented and located according to the array layout of the cells 100 in the memory cell region 159. In particular, considering cell 191-1 as typical, the contact 190-1 connecting to the first region source/drain 168-1 of cell 191-1 is aligned with the N−1 line 130 that couples to first regions (sources 95) of a first column 100-1 of cells 100 in memory cell region 159. Similarly, the contact 190-2 connecting to the second region drain/source 168-2 of cell 191-1 is aligned with the N line 130 that couples to second regions (drains 97) of the first column 100-1 of cells 100. The source 95 regions and the drain 97 regions are of course interchangeable and hence the first region in cells 100 may be either source or drain and the second regions may be either source or drain. The cell 191-1 has a gate 163a coupled to contact 190-3 whereby cell 191-1 causes the source-to-drain connection between source/drains 168-1 and 168-2, contacts 190-1 and 190-2 and N−1 line 130 and N line 130 to be coupled with a low impedance (short) or a high impedance (open) as a function of a control signal applied to gate 163a and contact 190-3. While the connection cell 191-1, when controlled to be conducting, couples the N−1 cell line 130 to the N cell line 130, the coupling can be to any number of other cell lines by operation of the transistors 191-2, 191-3, . . . and so on where any number of additional transistors 191 (not shown) may be provided based upon the size of the memory device 500.

In FIG. 4B and FIG. 5, memory devices (memory devices 400B and 500, respectively) are shown having a first region (memory region 156) having a plurality of memory cells (cell 100A and 100, respectively) including for each memory cell, a first cell region (source/drain 95), a second cell region (drain/source 97), a cell channel (96) between the first cell region and the second cell region and a charge storage region (66), a second region (non-memory region 157-2) having a plurality of transistors (191-1, 191-2, 191-3, . . . ) including for each transistor a first transistor terminal (terminal 168-1), a second transistor terminal (terminal 168-2), a transistor channel between the first transistor terminal and the second transistor terminal and a gate (62), a plurality of cell lines (130′) extending in the first region (memory region 156) and in the second region (non-memory region 157-2) where a first one of the cell lines (N−1 cell line 130′) electrically couples the first cell regions (sources 95) of first ones of the memory cells (the left column of memory cells 100-1) to a first one of the first transistor terminals (terminal 168-1 for transistor 191-1) and where a second one of the cell lines (N cell line 130′) electrically couples the second cell regions (drains 97) of the first ones of the memory cells (the left column of memory cells 100-1) to a second one of the first transistor terminals (168-2 for transistor 191-1). In the example described, the first one of the cell lines (N−1 cell line 130′) is adjacent the second one of the cell lines (N cell line 130′). Similarly, a first one of the cell lines (N cell line 130′) is adjacent a second one of the cell lines (N+1 cell line 130′) and a first one of the cell lines (N+1 cell line 130′) is adjacent a second one of the cell lines (N+2 cell line 130′).

While FIG. 5 has depicted with the non-memory region 157-2 for the memory device 500 like the non-memory region 157-2 for the memory device 400B of FIG. 4, in an alternate embodiment, the non-memory region 157-2 for the memory device 500 can have other forms such as the non-memory region 157-2 for the memory device 400A of FIG. 4A.

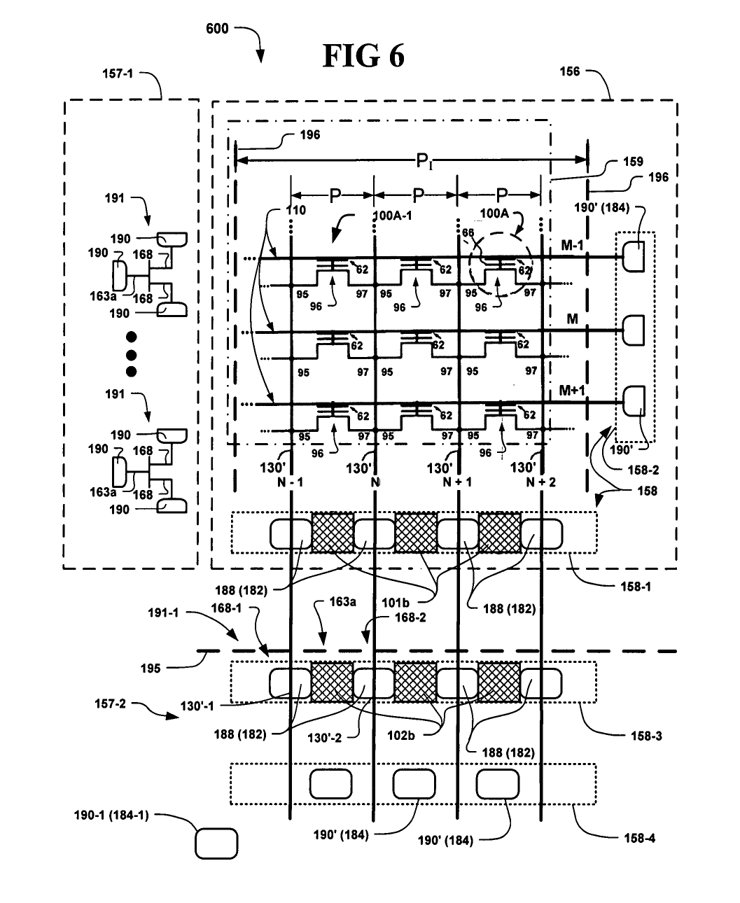

In FIG. 6, the memory device 600 is shown in schematic detail and is substantially the same as the memory device 500 in FIG. 5 except the cells 100A are typically of the form of cell 100A in FIG. 1A not having the additional L−1, L and L+1 cell lines 120 as in FIG. 5. However, in some embodiments, the any memory cell can be used in the FIG. 6 memory device 600. In the non-memory region 157-2 of FIG. 6, embedded logic 191, including by way of example the transistors 191-1, 191-2 and 191-3 as shown in FIG. 5 can be included in FIG. 6.

In general, FIG. 6 is a memory device 600 formed as a memory array of cells 100A (or any other cells). The memory device includes a memory region 156 including a plurality of memory cells 100A, each memory cell (when a cell 100 of FIG. 2A is employed) has a source, a drain and a channel between the source and the drain, a channel dielectric, a charge storage region and an electrically alterable conductor-material system in proximity to the charge storage region. The memory device includes a plurality of conductor lines 130′, 110, (120, not shown, see FIG. 5). The conductor lines include the lines 130′-1 and 130′-2 portions in region 158-3. The conductor lines lines 130′-1 and 130′-2 are in one embodiment transistor sources and drains (see region 168 hereinafter). The memory includes a non-memory region 157-2 having embedded logic including a plurality of transistors (such as transistors 191 in FIG. 5), each transistor for electrically coupling one of the conductor lines and each transistor including a transistor source, a transistor drain and a transistor gate.

In one embodiment, the memory cells 100A have charge storage regions, for a plurality of memory cells, substantially in alignment with the transistor gate of one of the transistors. The column of cells 100A-1, for example, have charge storage regions aligned with a transistor gate 163a between the source 168-1 and the drain 168-2 (see the arrangement in FIG. 5).

In one embodiment of the memory device 600, the conductor lines 130′ include first and second cell lines (N−1 and N, for example) connecting respectively to sources and drains of a first group of memory cells (column of cells 100A-1), where for a first one of the transistors (for example 191-1), the transistor source (168-1) is located substantially in alignment with one (N−1) of the first and second cell lines and the transistor drain (168-2) is located substantially in alignment with another one (N) of the first and second cell lines.

In one embodiment of the memory device, a plurality of transistors are connected where for the plurality of transistors the drain of one transistor is connected to the source of an adjacent transistor (see the connection 191-1, 191-2, 191-3, . . . in FIG. 5).

In one embodiment of the memory device, the conductor lines include a plurality of first cell lines (130′, for example) wherein the charge storage regions (for cells 100A in the column 100A-1) are substantially aligned between pairs of the first cell lines (130′ lines N−1 and N).

In one embodiment of the memory device, the plurality of conductor lines includes one or more first cell lines extending to the non-memory region where one or more of the first cell lines electrically couples the embedded logic without an intermediary element or with a conductive intermediary element where the conductive intermediary element is selected from the group consisting of contacts, diffusions, metal lines and transistors or combinations thereof.

In one embodiment of the memory device, the conductor lines (130′, for example) include a plurality of first cell lines where the charge storage regions are substantially aligned between pairs of the first cell lines, a plurality of second cell lines (110) for electrically coupling to the charge storage regions of a plurality of memory cells.

In FIG. 6, isolation regions such as 195 and 196 are optionally present. If present, provisions electrical coupling may be provided across the isolation. For example, a cell line 130′ can be couple across isolation 195 so as to electrically couple to the transistor source 168-1.

In FIG. 6, various contacts and contact holes are shown in the regions 158-1, 158-2, 158-3 and 158-4 and outside those regions at any arbitrary location (See contact 190-1 (in hole 184-1). Any of the contacts in or outside the regions may be self-aligned contacts or borderless contacts.

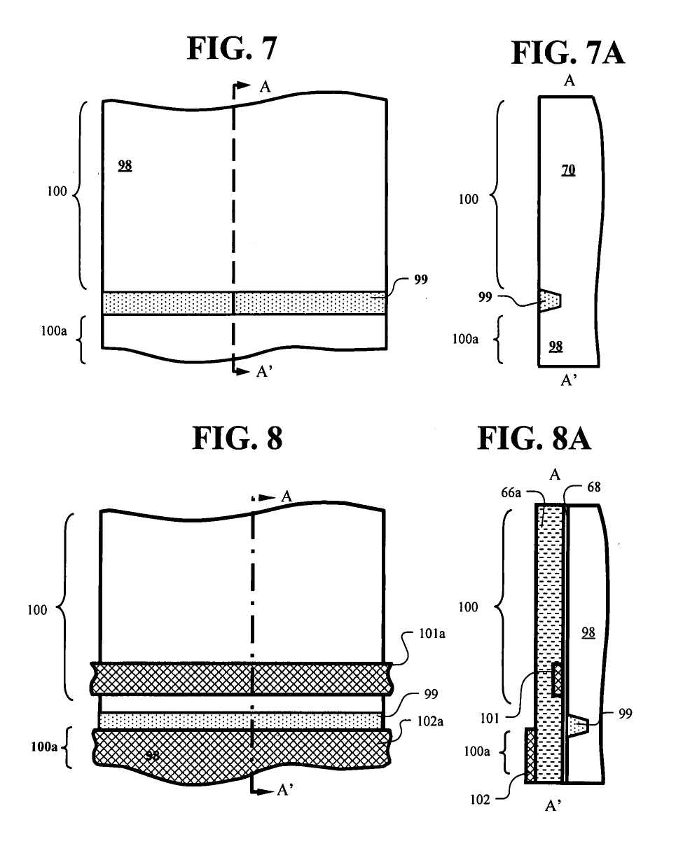

FIG. 7 depicts a top plan view and FIG. 7A depicts a cross-sectional side view of a semiconductor substrate used as the starting structure for the present specification.

Referring to FIG. 7, one particular example of the generalized manufacturing method starts with a structure in its top plan view shown in FIG. 7, which shows a semiconductor substrate 98. The substrate 98 is used as the starting material for arranging memory cells, an array of memory cells, and logic transistors supporting memory operations. A cross-sectional view of the material thus described is shown in FIG. 7A, wherein the substrate 98 is preferably a silicon of a first conductivity type (e.g. p-type). The substrate can be other types of selection, such as a Silicon-On-Insulator (SOI). A body 70 is arranged in the substrate by well-known techniques such as ion implantation, and is assumed having the first conductivity type. The body 70 is isolated from the substrate 98 by semiconductor region having a second type of conductivity (e.g. deep n-type Well). An isolation region 99 is formed in the substrate 98 to define and isolate memory cell region 100 from non-memory cell region 100a by employing proper isolation scheme such as LOCOS or shallow-trench-isolation (STI) well-known in the arts. Other types of isolation technique such as junction-isolation well-known in the art can be employed instead to form the isolation region 99. The non-memory cell region 100a typically includes peripheral regions having decoder, sense amplifier, control logics etc, typically for supporting memory operations.

Typically, logic circuits comprise transistors having a first type of channel (e.g. n-channel transistors, or n-FETs) and/or a second type of channel (e.g. p-channel transistors, or p-FETs) and are formed in the non-memory cell region 100a. Ion implantation techniques and masking steps are employed to selectively introduce impurity into the non-memory cell region 100a. The depth and concentration of the impurity can be controlled by the energy and dosage of the impurity ions. Typically, such ion implant can be done in one-step or in multi-steps (e.g. an implant step arranging a well, an implant step setting the threshold voltage, and an implant step controlling the punch through leakage of the transistors). As will be appreciated, reference indicators throughout the drawings are shown only in a few places of identical regions in order not to overcomplicate the drawings.

FIG. 8 and FIG. 8A represent elements and steps in connection with arranging a Charge Storage Region (“CSR”).

The steps include arranging a first insulator 68 over the substrate 98 with thickness preferably at about 7 nm to about 9 nm. The insulator is preferably made of oxide arranged by employing conventional thermal oxidation, HTO, or by in-situ steam generation (“ISSG”) techniques well-known in the art.

The steps include arranging a nitride 101 on top of the first insulator 68 using a conventional LPCVD technique. The thickness of the nitride is chosen such that it can withstand a contact etch that is used to etch away an inter-layer-dielectric “ILD” such as oxide. Typical nitride thickness can be from 20 nm to 100 nm.

The steps include arranging a photo-resistant material (“photo-resist” hereinafter) on the structure surface followed by a masking step using conventional photo-lithography technique to selectively remove the photo-resist leaving a plurality of photo-resist line traces oriented in a first direction (row direction).

The steps include etching the exposed nitride 101 until the insulator 68 is observed, which acts as an etch stop to nitride etch. The portions of nitride still underneath the remaining photo-resist are unaffected by this etch process. This step forms a plurality of nitride line traces 101a oriented in the first direction (row direction).

The steps include stripping the photo-resist followed by removing the oxide 68 in the exposed area.

The steps include arranging an oxide in the exposed area by employing thermal oxidation, HTO, or by ISSG techniques to re-form the oxide layer 68.

The steps include arranging a layer of charge storage material 66a such as polysilicon over the structure using, for example, conventional LPCVD technique with polysilicon film doped in-situ or by a subsequent ion implantation. The polysilicon layer 66a thus formed is used for forming CSR 66 of memory cell, and can be doped with impurity of a second conductivity type at a doping level in the range of about 1×1018 atoms/cm³ to about 5×1021 atoms/cm³. The polysilicon layer 66a is with a thickness, for example, in the range from about 50 nm to 70 nm. Preferably, the topography of the polysilicon layer 66a thus formed is substantially planar.

The steps include arranging a nitride 102 on top of the charge storage material 66a using a conventional LPCVD technique.

The steps include arranging a mask and etching the nitride 102 by using conventional photo-lithography and etching techniques to form a plurality of nitride line traces 102a oriented in the first direction.

The resulting structure (topview) and a cross-section along line AA′ are shown in FIGS. 8 and 8A, respectively.

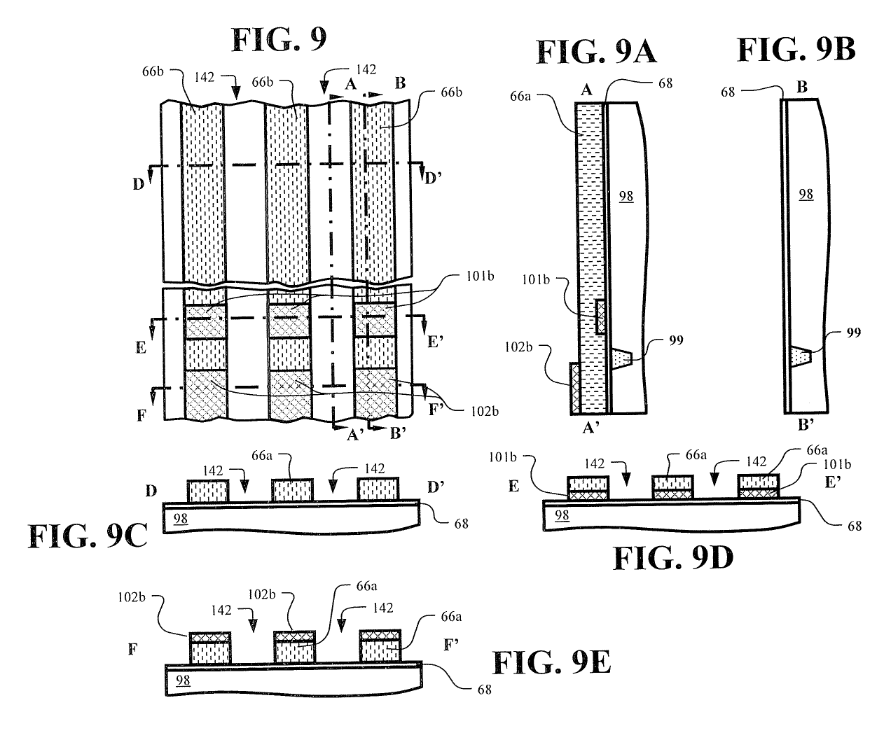

FIG. 9, FIG. 9A, FIG. 9B, FIG. 9D, FIG. 9E and FIG. 9F represent elements and steps in connection with further arranging of the Charge Storage Region (“CSR”).

The steps include arranging a plurality of photo-resist lines using conventional photo-lithography and masking step. A hard-mask approach (e.g. forming a dielectric such as oxynitride under the photo-resist is preferred for the masking step). This step exposes portions of nitride 102a and portions of the charge storage material 66a to the air.

The steps include arranging a first plurality of nitride elements 102b by removing the exposed nitride 102a using conventional etching technique.

The steps include arranging a plurality of poly lines 66b orientated in a second direction (or “column direction”) with each pair of them spaced apart by a first trench 142. This can be done by employing conventional dry etching techniques (e.g. RIE) to remove the exposed polysilicon layer 66a. The step exposes portions of the nitride line traces 101a in the first trench 142.

The steps include removing the exposed portions of nitride traces 101a by a dry etching technique to form a second plurality of nitride elements 101b each self-aligned to a poly line 66b. The nitride elements 101b each provide protection for self-align contact formation on bit-lines in later steps of the process. The remaining photo-resist is then removed using conventional means. The resulting structure (topview) and a cross-section along line AA′, BB′, DD′, EE′ and FF′ are shown in FIG. 9, FIG. 9A, FIG. 9B, FIG. 9D, FIG. 9E and FIG. 9F, respectively. Note, although each nitride element 102b is shown self-aligned to a corresponding polysilicon layer 66a and to a nitride element 101b of the second plurality type. The pattern of each nitride element 102b in general can be defined in any shape of polygon suited for logic transistor gate and need not be self-aligned to the other elements.

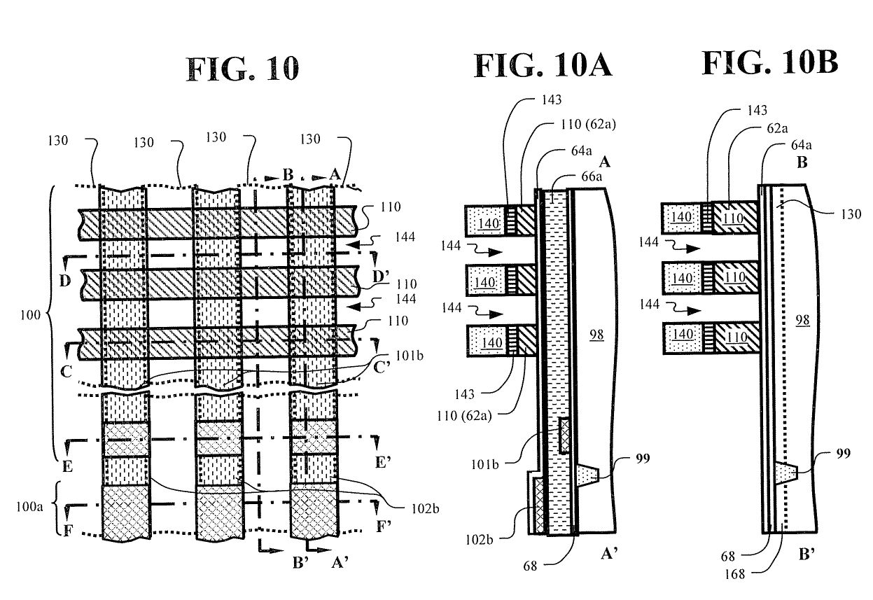

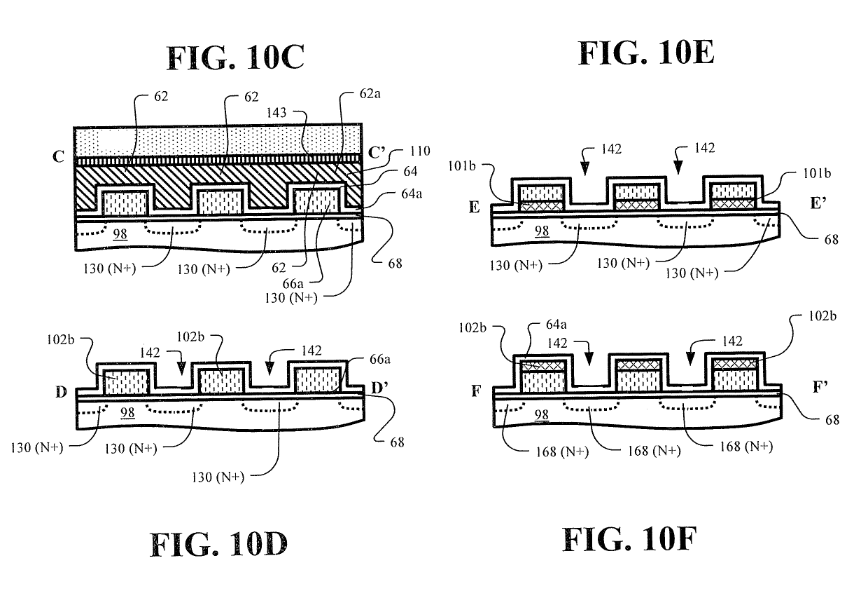

FIG. 10, FIG. 10A, FIG. 10B, FIG. 10C, FIG. 10D, FIG. 10E and FIG. 10F represent elements and steps in connection with arranging conductor lines, word lines and bit lines.

The steps include applying a photo-resist followed by a masking step to expose the memory cell region 100. In a first alternate embodiment, the masking step can also expose a selective portion in the non-memory cell region 100a.

The steps include performing an ion implant step to dope the exposed silicon region in the second type of conductivity to form diffusion regions self-aligned to the first trench 142. Such diffusion regions form the bit-lines 130 in cell region 100a. For the first alternate embodiment, the ion implant step also forms source/drain 168 for transistors in the non-memory cell region 100a. The remaining photo-resist is then removed afterward.

The steps include arranging a second insulator layer 64a over the exposed charge storage layer 66a with thickness preferably at about 7 nm to about 9 nm. The insulator can be, e.g., oxide deposited by employing conventional HTO (preferred), thermal oxidation, TEOS or ISSG deposition techniques.

The steps include arranging a layer of conductive material 62a such as polysilicon over the structure using, for example, conventional LPCVD technique with polysilicon film doped in-situ or by a subsequent ion implantation. Typically, the conductive material 62a is with a thickness thick enough to fill the first trenches 142 and can be on the order of, for example, about 30 nm to 80 nm.

The steps include arranging a dielectric 143 (e.g. nitride) over the conductive layer 62a with thickness preferably at about 10 nm to about 50 nm.

The steps include arranging a plurality of word lines 110 orientated in the first direction (or “row direction”) with each pair of them spaced apart by a second trench 144. This can be done by forming photo-resist traces 140 using conventional photo-lithography and masking step, followed by a dry etching technique (e.g. RIE) to remove exposed conductive material 62a. Each word line 110 connects the ballistic gate (BG) 62 of cells on the same row (see FIG. 27C).

The resulting structure and a cross-section along line AA′, BB′, CC′, DD′, EE′ and FF′ are shown in FIG. 10, FIG. 10A, FIG. 10B, FIG. 10C, FIG. 10D, FIG. 10E and FIG. 10F respectively.

FIG. 11, FIG. 11A, FIG. 11B, FIG. 11C, FIG. 11D FIG. 11E and FIG. 11F represent elements and steps in connection with arranging the Charge Storage Region (“CSR”).

The steps include etching the exposed second layer 64a followed by etching the exposed charge storage layer 66a until the first insulator 68 is observed, which acts as an etch stop. The portions of layer 66a underneath the remaining photo-resist are unaffected by this etch process. This step forms a plurality of CSR 66. The step also exposes the first plurality of nitride elements 102b and the second plurality of nitride elements 101b. The portions of layer 66a underneath the nitride elements 102b are unaffected by this etch process. The remaining photo-resist is then removed using conventional means. The top plan view of the resulting structure is shown in FIG. 11 with word-lines line 110 interlaced with the second trenches 144. The cross-sectional views along lines AA′, BB′, CC′, DD′, EE′ and FF′ of the resulting structure are collectively illustrated in FIG. 11, FIG. 11A, FIG. 11B, FIG. 11C, FIG. 11D FIG. 11E and FIG. 11F, respectively.

FIG. 12, FIG. 12A, FIG. 12B, FIG. 12C, FIG. 12D, FIG. 12E and FIG. 12F represent elements and steps in connection with arranging oxides in trenches adjacent memory cell elements and arranging the word lines.

Optionally, the steps include arranging an insulating layer (not shown) such as oxide on sidewalls of word-lines 110 and CSR 66 exposed to the trench 144. The oxide can be formed by for example performing a thermal oxidation step using rapid-thermal-oxidation (RTO) technique, and can have a thickness at about 2 nm to about 8 nm.

The steps include arranging a thick dielectric layer (e.g. oxide) to fill the trenches 144 by using well-known techniques such as conventional LPCVD. The oxide dielectric is then selectively removed to leave oxide blocks 146 in region within the trenches 144. The preferable structure is with the top surface of the oxide blocks 146 substantially co-planar with the top surface of the nitride dielectric 143. This can be done by, for example, employing a chemical-mechanical polishing (CMP) process to planarize the thick oxide followed by an RIE (reactive ion etch) using nitride dielectric 143 as a polishing and/or etching stopper. An optional oxide over-etching step follows as needed to clear any oxide residue on the nitride dielectric 143. Thereby, the process leaves oxide only in trenches 144 to form oxide blocks 146 self-aligned to the trenches 144. The top plan view of the resulting structure is illustrated in FIG. 12 with wordlines 110 interlaced with the oxide line blocks 146. The cross-sectional views along lines AA′, BB′, CC′, DD′, EE′ and FF′ of the resulting structure are collectively illustrated in FIG. 12, FIG. 12A, FIG. 12B, FIG. 12C, FIG. 12D, FIG. 12E and FIG. 12F.

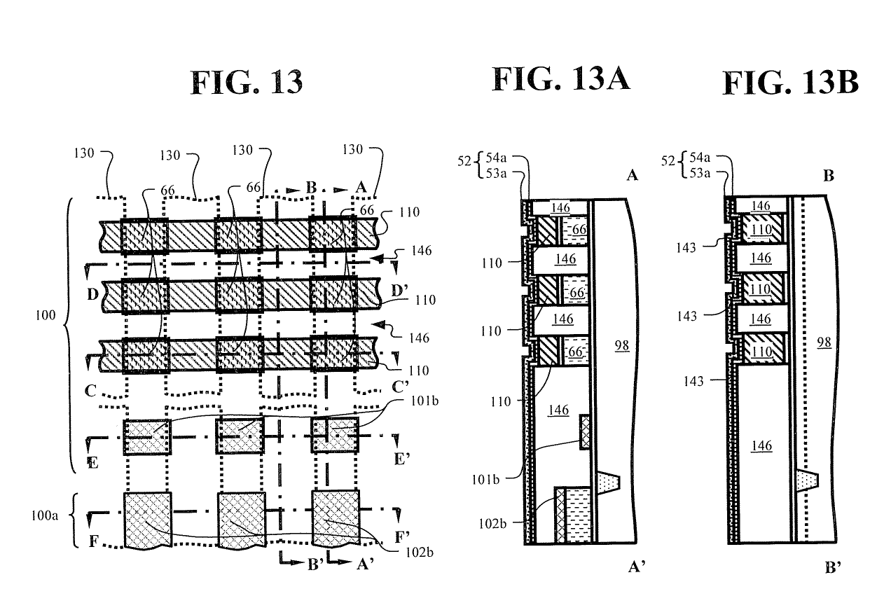

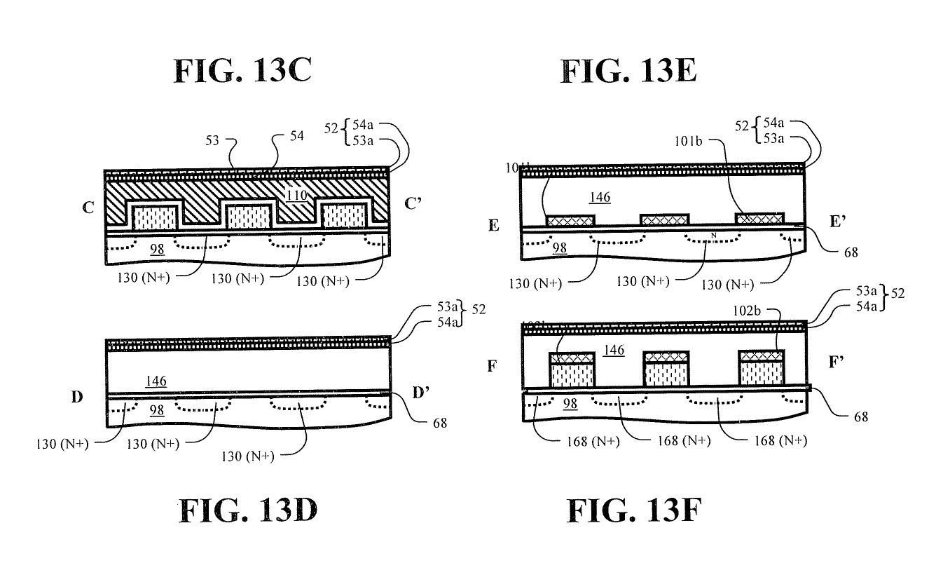

FIG. 13, FIG. 13A, FIG. 13B, FIG. 13C, FIG. 13D, FIG. 13E and FIG. 13F represent elements and steps in connection with arranging multilevel dielectrics for filters and other elements.

The steps include removing the nitride dielectric 143 via conventional etching step (e.g. using hot phosphoric acid).

The steps include arranging a filter 52 having multi-layers dielectrics over the word-lines 110. In a specific embodiment, a third insulator 54a (BD) and a fourth insulator 53a (TD) are considered as the multi-layers dielectrics for the filter 52. The third insulator layer 54a such as nitride is formed over the word-lines 110 by employing thermal nitridation such as rapid-thermal-nitridation (RTN) in NH3 ambient at 1050 C. The third insulator 54a has a thickness preferably at about 2 nm to about 5 nm. The process is continued by forming the fourth insulator layer 53a such as oxide over the third insulator 54a. The fourth insulator can be formed by using thermal oxidation, HTO, TEOS, or ISSG techniques well-known in the art. The fourth insulator 53a has a thickness preferably at about 2 nm to about 4 nm. The third and fourth insulator layers 54a and 53a are used as BD 54 and TD 53, respectively, of the memory cells. The top plan view of the resulting structure is illustrated in FIG. 13, and the cross-sectional views along lines AA′, BB′, CC′, DD′, EE′ and FF′ of the resulting structure are collectively illustrated in FIG. 13, FIG. 13A, FIG. 13B, FIG. 13C, FIG. 13D, FIG. 13E and FIG. 13F, respectively.

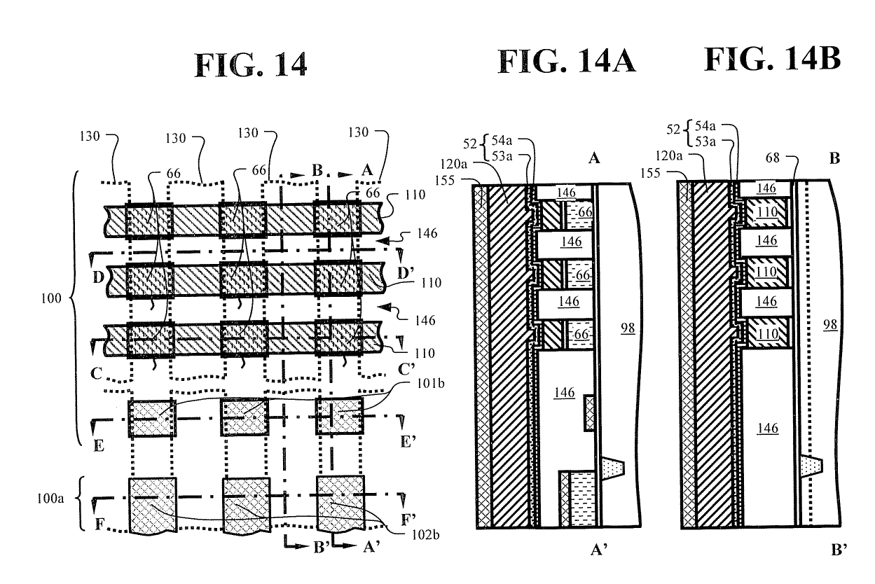

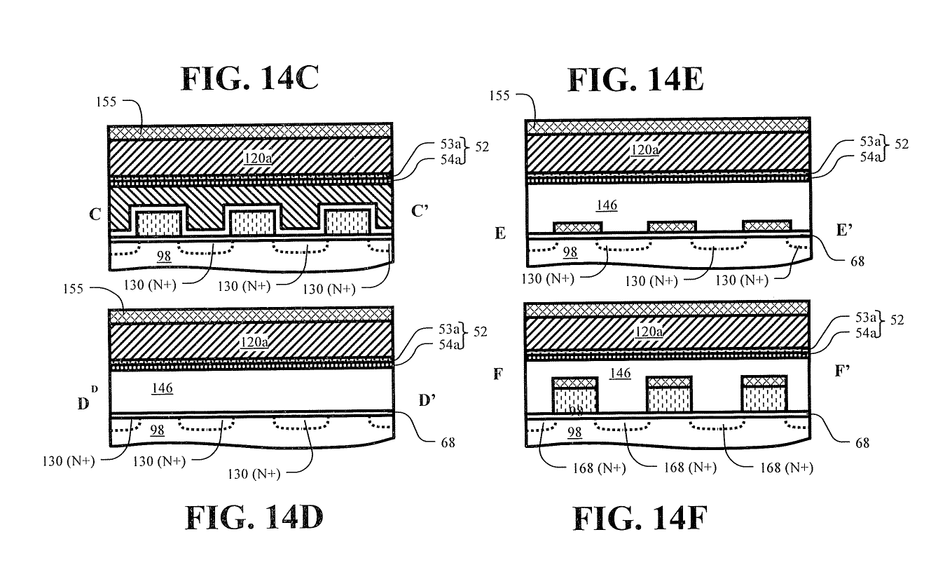

FIG. 14A, FIG. 14B, FIG. 14C, FIG. 14D, FIG. 14E and FIG. 14F represent elements and steps in connection with arranging a Self-Aligned-Contact (SAC) etching-stop layer.

The steps include arranging a conductor 120a on top of the filter 52 (including 53a & 54a) as the TG conductor. A p+ poly Si atop with a tungsten silicide is preferably chosen for the TG conductor. The thickness of the TG conductor can be range from 0.05 um to 0.2 um pending on the technology node chosen. Typically, the TG conductor thickness is thinner for more advanced technology node. For example, 70 nm (or 0.07 um) for the TG conductor is preferred for a 45 nm node technology.

The steps include arranging a first thick nitride 155 on top of the TG conductor using conventional LPCVD technique. The thickness of the first thick nitride 155 is chosen such that it can withhold contact etch that is used to etch away inter-layer-dielectric “ILD” such as oxide. Typical nitride thickness can be from 20 nm to 100 nm.

The resulting structure and their cross-sections along lines AA′, BB′, CC′, DD′, EE′ and FF′ are shown in FIG. 14A, FIG. 14B, FIG. 14C, FIG. 14D, FIG. 14E and FIG. 14F, respectively.

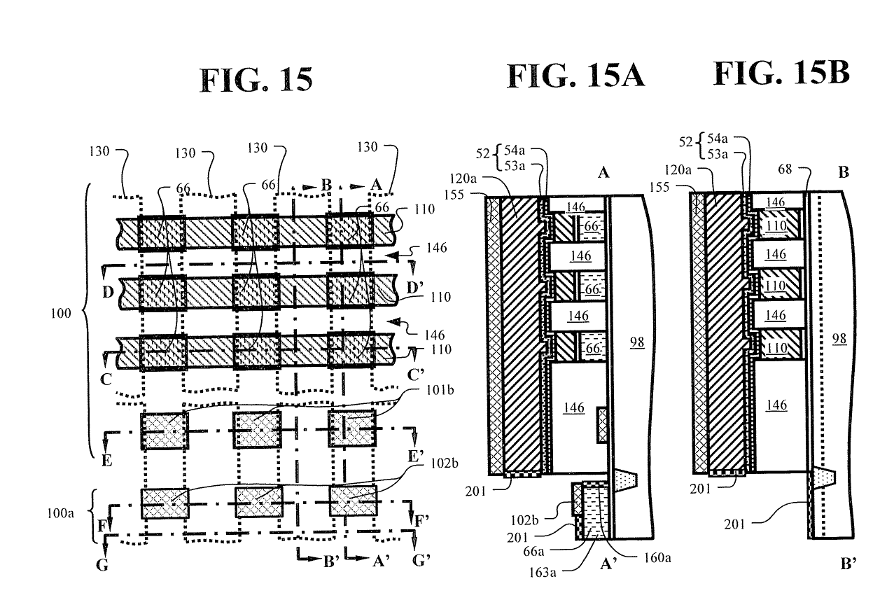

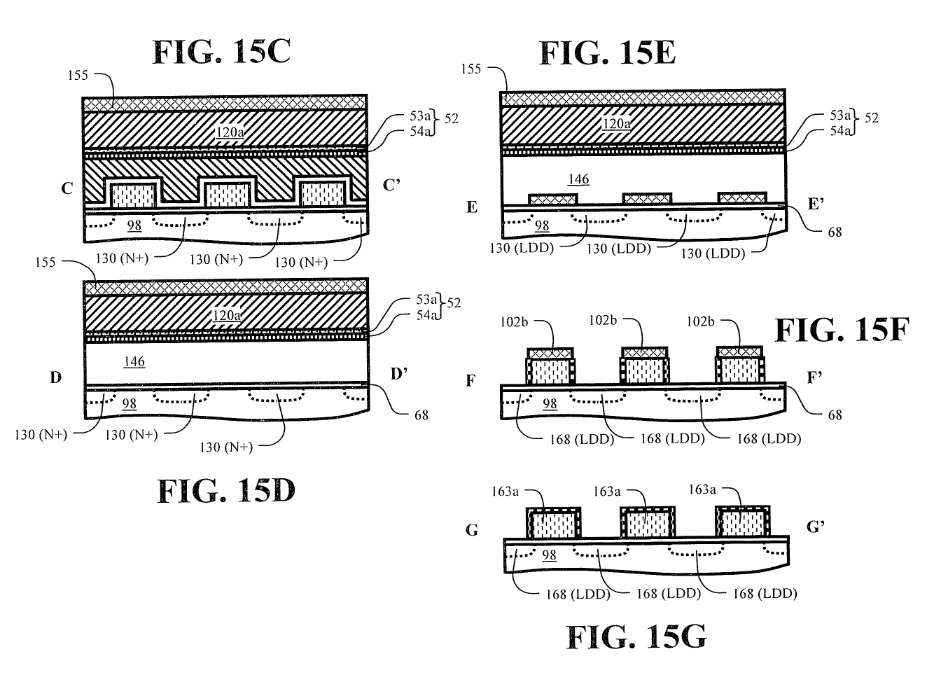

FIG. 15A, FIG. 15B, FIG. 15C, FIG. 15D, FIG. 15E, FIG. 15F and FIG. 15G represent elements and steps in connection with arranging embedded CMOS logic transistors.

The steps include arranging a photo-resist covering the memory cell regions 100 using conventional photo-lithography and masking step. This step protects the first thick nitride 155 in the memory cells regions 100 but exposes the first thick nitride 155 in the non-memory cell regions 100a.

The steps include removing the first thick nitride 155 and the TG conductor 120a using a dry etching technique (e.g. RIE). The step exposes filter 52 in the non-memory cell regions 100a. The process is further continued by removing the filter 52, the oxide blocks 146, and the first insulator 68 using dry etching technique to expose the first plurality of nitride elements 102b and the substrate 98 in the non-memory cell regions 100a.

The steps include stripping the photo-resist.

The steps include arranging an optional photo-resist using conventional photo-lithography and masking step to selectively expose portions of nitride elements 102b in the non-memory cell region 100a.

The steps include removing the exposed portions of nitride elements 102b by performing a nitride etch step. This step exposes a portion of the polysilicon 66a. Such etch has no effect on the nitride elements under the photo-resist.

The portion of polysilicon 66a under the remaining nitride elements 102b can be used as the gate of transistors 163a or as a resistor (not shown).

The steps include arranging an optional insulator PolyReOX 160a on the exposed polysilicon and silicon surfaces including sidewalls of TG conductor 120a, sidewalls and the exposed portion of transistor gates 163a, and the substrate 98. The insulator 160a thus formed on the substrate 98 merges with the first insulator 68. The insulator 160a is preferably an oxide formed by thermal oxidation technique.

The steps include in a second alternate embodiment, arranging optional shallow diffusion regions (e.g. LDD regions) for the first type of channel transistor (n-channel transistors). This step is done by forming a photo-resist using conventional photo-lithography and masking step to selectively expose regions in the non-memory cell regions for the first channel type of logic transistors. This step is followed by ion implantation steps implanting proper type of impurity into regions adjacent to the gate 163a and by a step stripping the photo-resist.

The steps include arranging shallow diffusion regions (e.g. LDD regions) for the second type of channel transistor (p-channel transistor) using method similar to those described above.

The resulting structure and their cross-sections along lines AA′, BB′, CC′, DD′, EE′, FF′ and GG′ are shown in FIG. 15A, FIG. 15B, FIG. 15C, FIG. 15D, FIG. 15E, FIG. 15F and FIG. 15G, respectively.

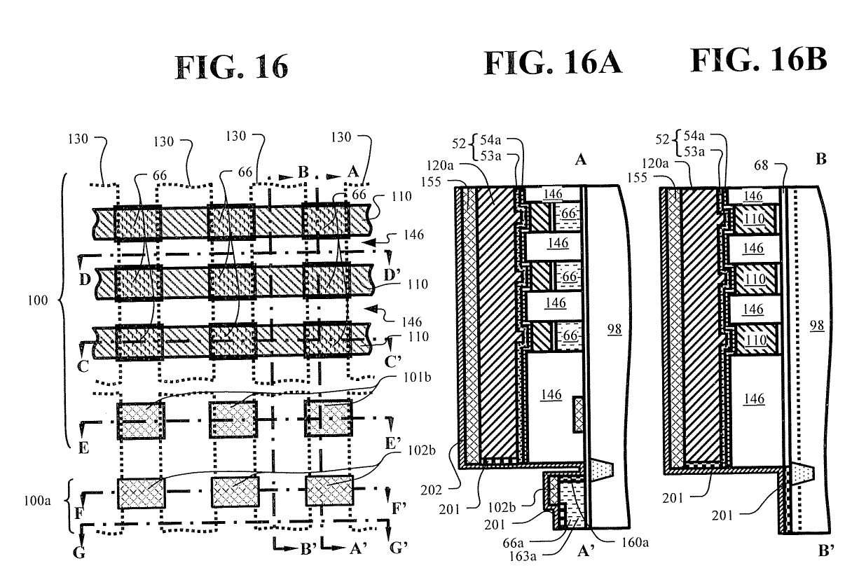

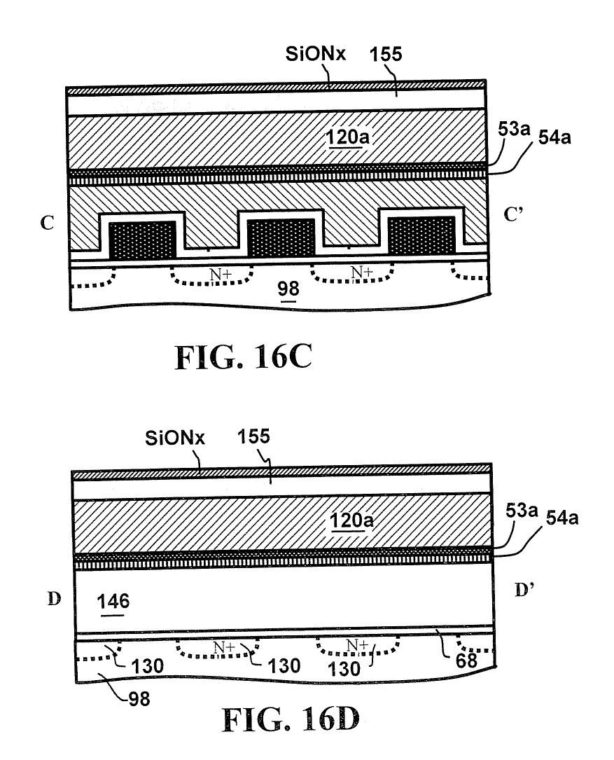

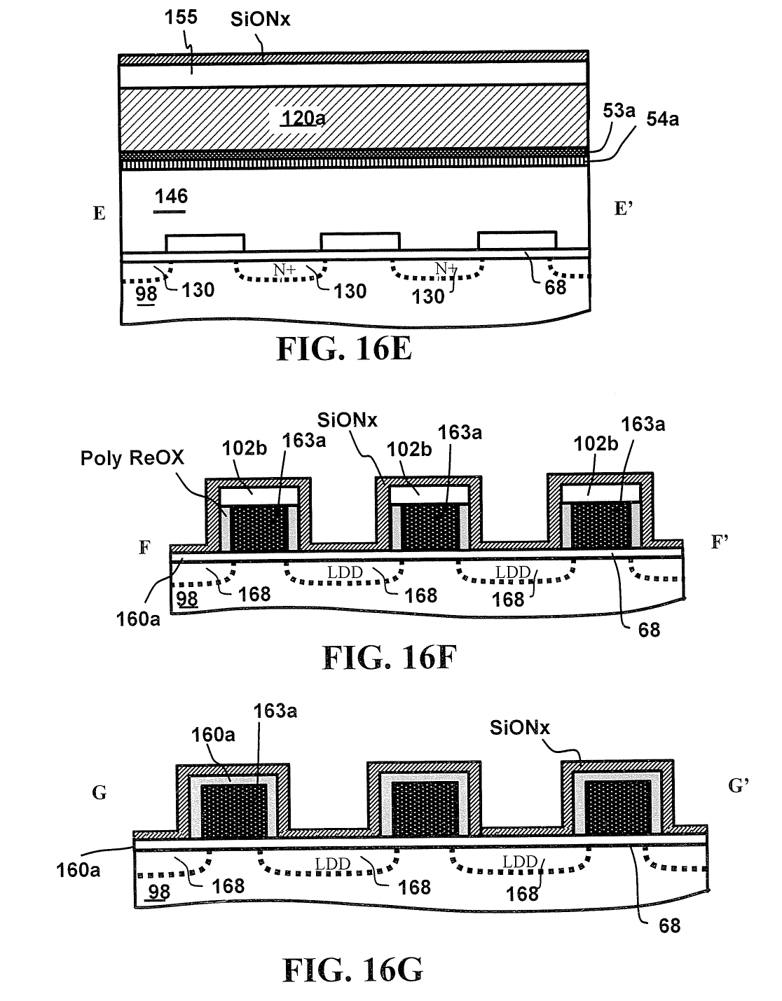

FIG. 16A, FIG. 16B, FIG. 16C, FIG. 16D, FIG. 16E, FIG. 16F and FIG. 16G, represent elements and steps in connection with further arranging embedded CMOS logic.

The resulting structure and their cross-sections along lines AA′, BB′, CC′, DD′, EE′, FF′ and GG′ are shown in FIG. 16A, FIG. 16B, FIG. 16C, FIG. 16D, FIG. 16E, FIG. 16F and FIG. 16G, respectively.

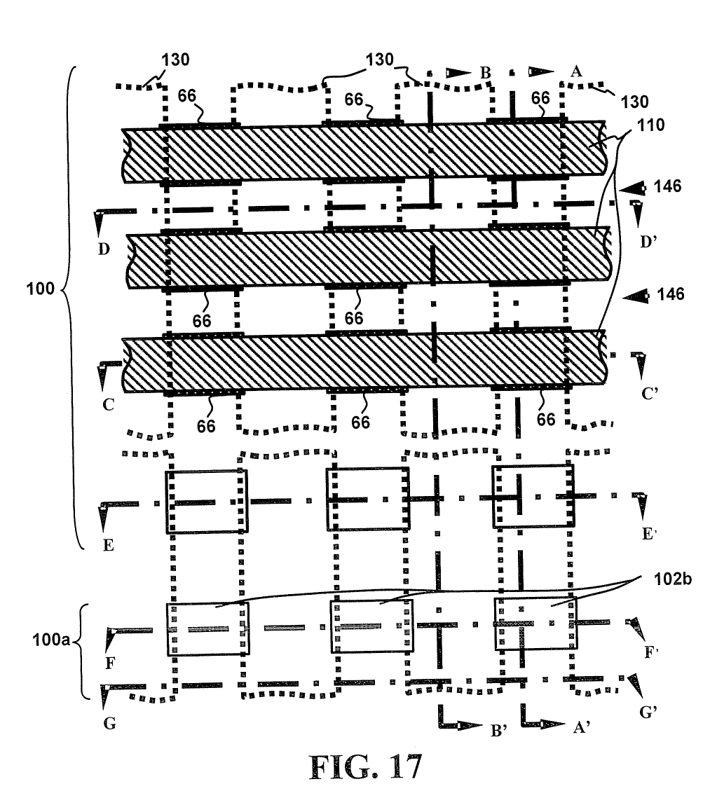

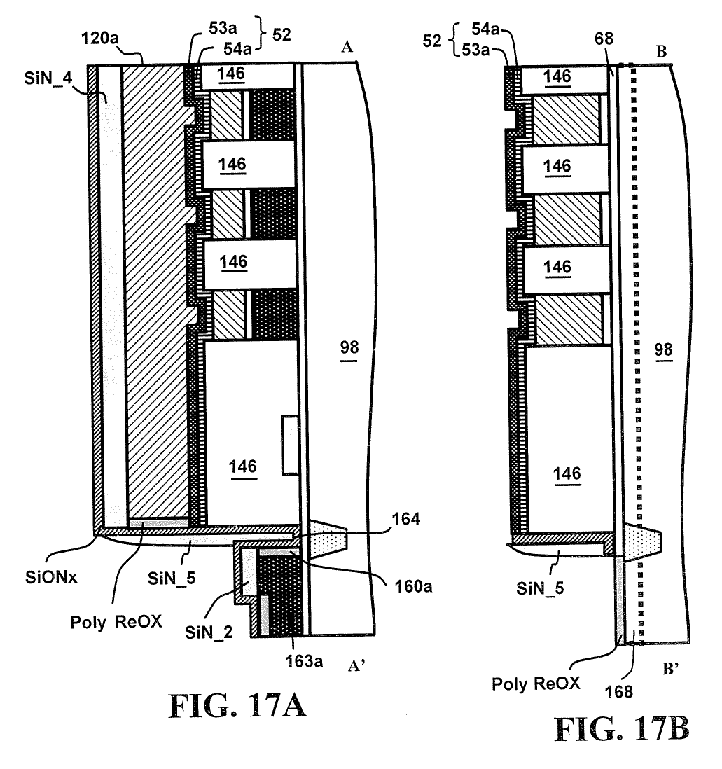

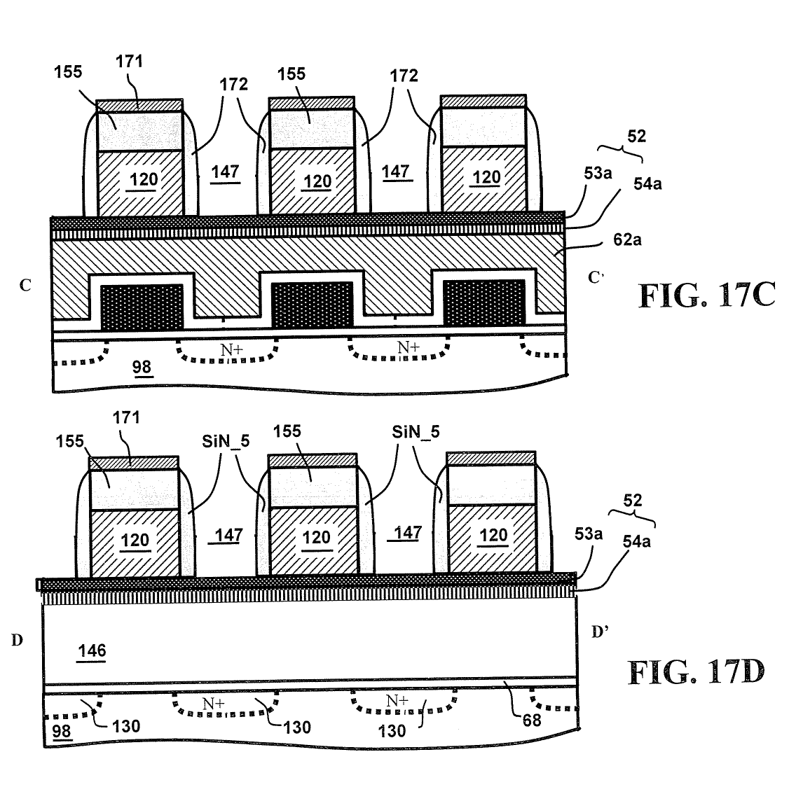

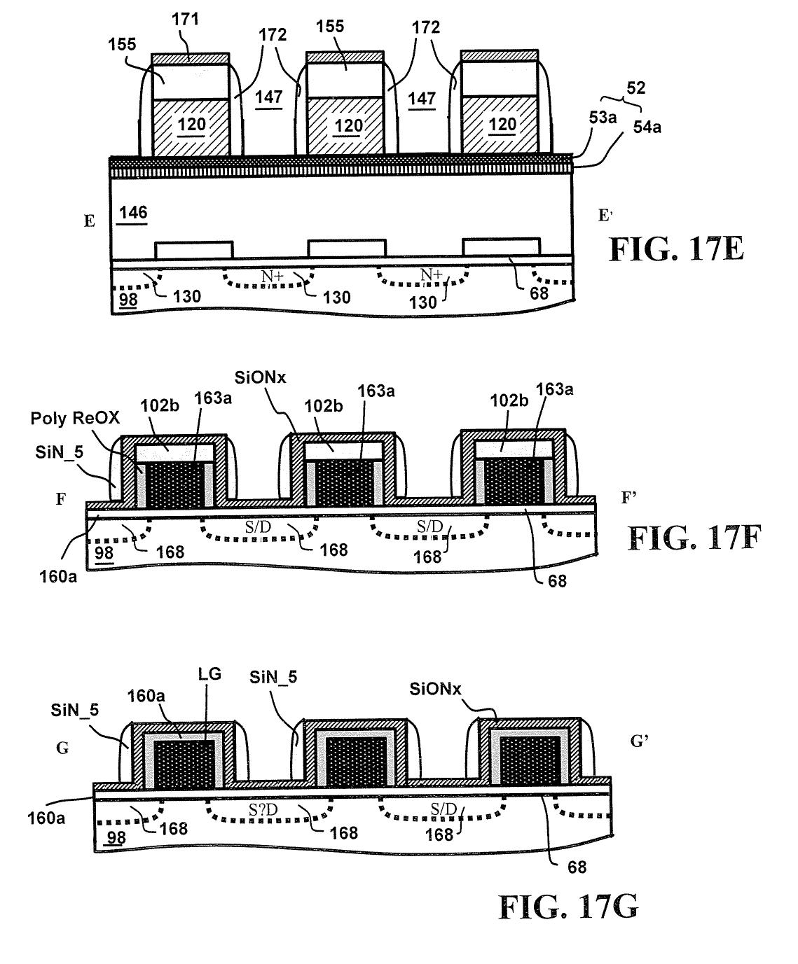

FIG. 17A, FIG. 17B, FIG. 17C, FIG. 17D, FIG. 17E, FIG. 17F and FIG. 17G represent elements and steps in connection with arranging Tunneling-gate (“TG”) lines.

The steps include arranging a plurality of TG lines 120 orientated in the second direction (or “column direction”) with each pair of them spaced apart by a third trench 147. This can be done by first forming a layer of oxynitride (SiONx) 171 to be used as a hard mask on the TG conductor 120a, followed by conventional photo-lithography and masking steps to define TG lines 120. Next, a dry etch (e.g. RIE) is performed to remove oxynitride (SiONx) 171 in exposed regions followed by a step stripping the photo-resist. The step is followed by etching the first thick nitride 155, and the TG conductor 120a to expose portions of the filter 52 in the third trench 147.

The etching has no effect in non-memory cell regions, which are covered by the hard mask of SiONx 171.

The steps include arranging an optional oxide on sidewalls of the TG conductor 120a (not shown).

The steps include doping the WL conductor 62a in the trench 147 regions by employing ion implantation technique (e.g. implanting phosphorous impurity). The TG lines 120 are protected by the hard mask and the nitride 155 during the implantation, and the implant has no effect on the TG lines 120.

The steps include applying a thermal step to activate the implanted impurity and to diffuse the impurity laterally to dope WL regions under the TG conductor.

The steps include arranging a thin nitride layer on top of the thick nitride layer 155. The thickness of the thin nitride can be range from 10 nm to 30 nm pending on the technology node chosen. Typically, the thin nitride thickness is thinner for more advanced technology node. For example, 10 nm (or 0.01 um) for the thin nitride is preferred for a 45 nm node technology.

The steps include dry etching back the thin nitride layer by using a conventional technique (e.g. RIE) to form nitride spacers SiN_5 172 on both sidewalls of each TG line 120. The etch uses the oxynitride SiONx 171 as an etch stop to protect the first thick nitride 155.

The etch also forms spacers SiN_5 along sidewall of the gate 163a and along sidewalls of oxide block 146 and sidewalls of the TG conductor 120a.

The steps include arranging source/drain diffusion regions 168 for the first channel type of transistor in the second alternate embodiment. This step is done by forming a photo-resist using conventional photo-lithography and masking step to selectively expose regions in the non-memory cell regions for the first channel type of logic transistors. This step is followed by ion implantation steps implanting impurity of proper type, dosage, and energy into region adjacent to the gate 163a. The photo-resist is stripped after the implantation step.

The steps include arranging source/drain diffusion regions for the second channel type of transistor using method similar to those described for the first channel type of transistors. The source/drain regions of the second channel type of transistor has similar cross-section as that of the first channel type of transistor. In the drawings illustrated herein, only the first channel type of transistor is shown to not complicate the drawings. Also, structures are also shown for the first alternate embodiment to illustrate the present invention.

The resulting structure and their cross-sections along lines AA′, BB′, CC′, DD′, EE′, FF′ and GG′ are shown in FIG. 17A, FIG. 17B, FIG. 17C, FIG. 17D, FIG. 17E, FIG. 17F and FIG. 17G, respectively.

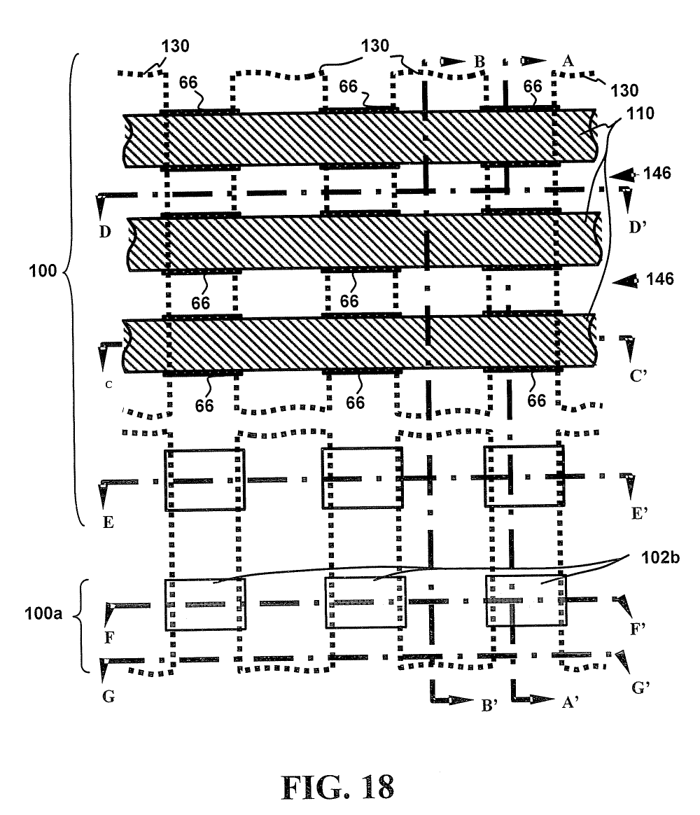

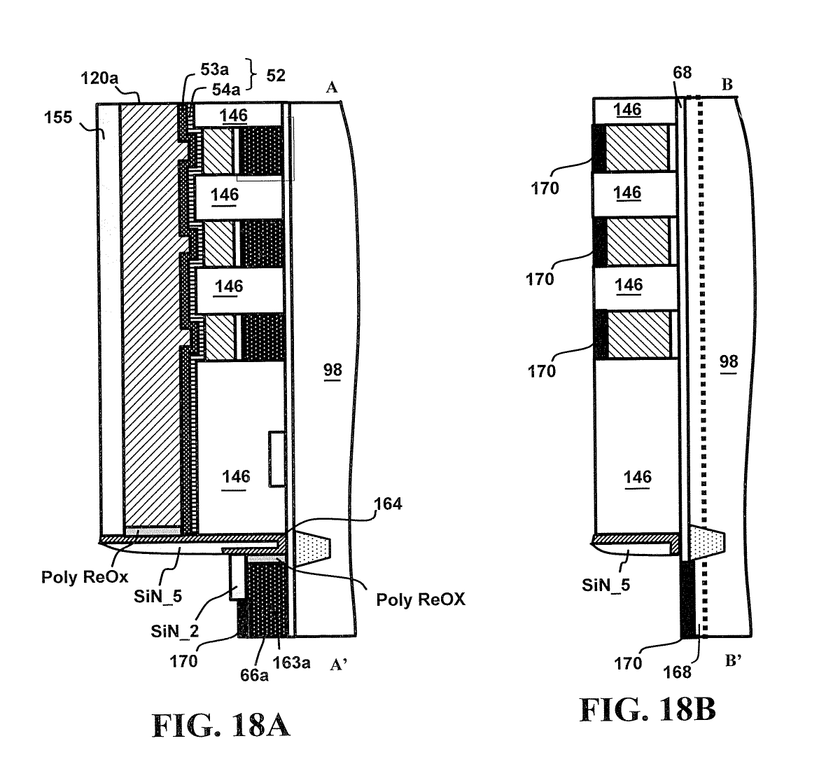

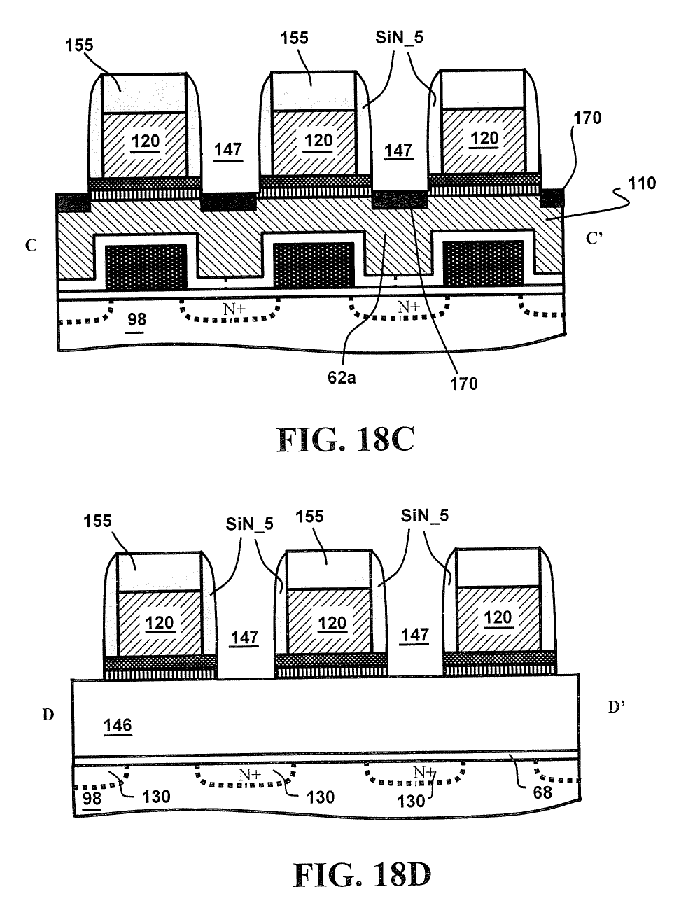

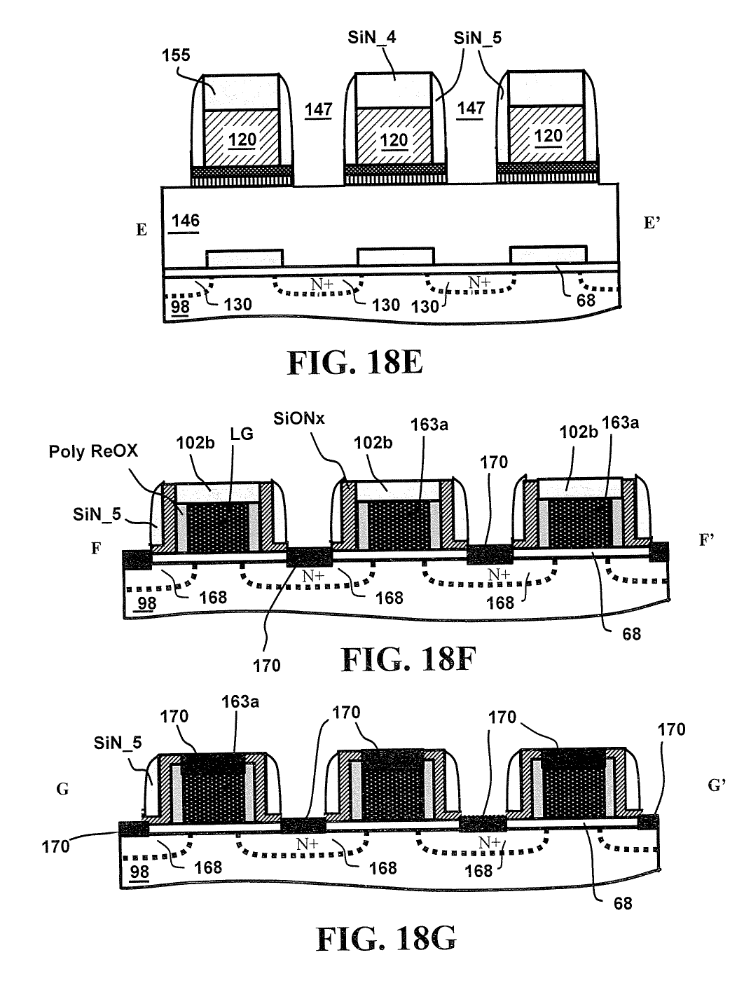

FIG. 18, FIG. 18A, FIG. 18B, FIG. 18C, FIG. 18D, FIG. 18E, FIG. 18F and FIG. 18G represent elements and steps in connection with arranging salicide regions and further processing.

While the hardmask 171 still in place, the process is continued by removing the TD oxide 53a of filter 52 to expose BD nitride 54a within trench 147 by using conventional oxide etch technique (e.g. RIE) followed by a nitride etch removing the BD nitride 54a of the filter 52 to expose WL conductor 62a in the trench 147 and in the peripheral region of the array (not shown).

The steps include removing the hardmask 171 by using conventional etching technique. The step exposes the top portion of the first thick nitride 155, the gate 163a and the source/drain diffusions 168 to the air.

The steps include arranging salicide regions 170 on the top portion of gate 163a and the source/drain diffusions 168 by employing conventional salicide techniques. For example, this can be done by depositing a layer of metal (e.g. Ni) followed by a thermal treatment (e.g. RTA) to react Ni with the silicon to form a Ni-silicon alloy. Other salicide technique, such as FUSI (Fully-Silicided gate) well-known in the art can be employed to form fully silicided gate. Un-reacted Ni is then removed by a conventional wet-etching technique to leave the Ni-silicide alloy (salicide 170), which is self-aligned to the conductive regions 163a and 168 lying thereunder. This step also forms salicide on the exposed WL conductor 62a of each word-line 110.

The resulting structure and their cross-sections along lines afore-mentioned are shown in FIG. 18, FIG. 18A, FIG. 18B, FIG. 18C, FIG. 18D, FIG. 18E, FIG. 18F and FIG. 18G.

FIG. 19, FIG. 19A, FIG. 19B, FIG. 19C, FIG. 19D, FIG. 19E and FIG. 19F represent elements and steps in connection with arranging a nitride layer and further processing.

The steps include arranging a thin oxide layer 175 on top of the structure. The oxide layer 175 can be formed by using conventional techniques such as LPCVD, and can be also through HTO oxide technique. The thickness of the oxide layer can be in the range from 10 nm to 30 nm.

The steps include arranging a second thick nitride SiN_6 178 on top of the thin oxide layer 175 using conventional LPCVD technique. The thickness of the second thick nitride 178 is chosen such that it provides strain to TG and BG conductors to effectively generate Piezo-Ballistic transport effect for the charge injection. Typical nitride thickness can be from 20 nm to 150 nm. The second thick nitride SiN_6 178 also provides effects on enhancing performance (e.g. current drive and power saving) of the logic transistors and provides function serving as a contact etching stopper for forming borderless contacts. Form a photo-resist (PR) on top of the structure using conventional photo-lithography techniques.

The steps include applying a mask to define the PR exposing a portion of the second thick nitride 178 in region adjacent to the cell area. The PR thus formed covers the thick nitride 178 in the rest of the area.

The steps include removing the second thick nitride 178 in the exposed area by using conventional etching techniques (e.g. RIE). This step uses the oxide layer 175 as an etching stop layer. The resulting structure and their cross-sections along lines afore-mentioned are shown in FIG. 19, FIG. 19A, FIG. 19B, FIG. 19C, FIG. 19D, FIG. 19E and FIG. 19F, respectively.

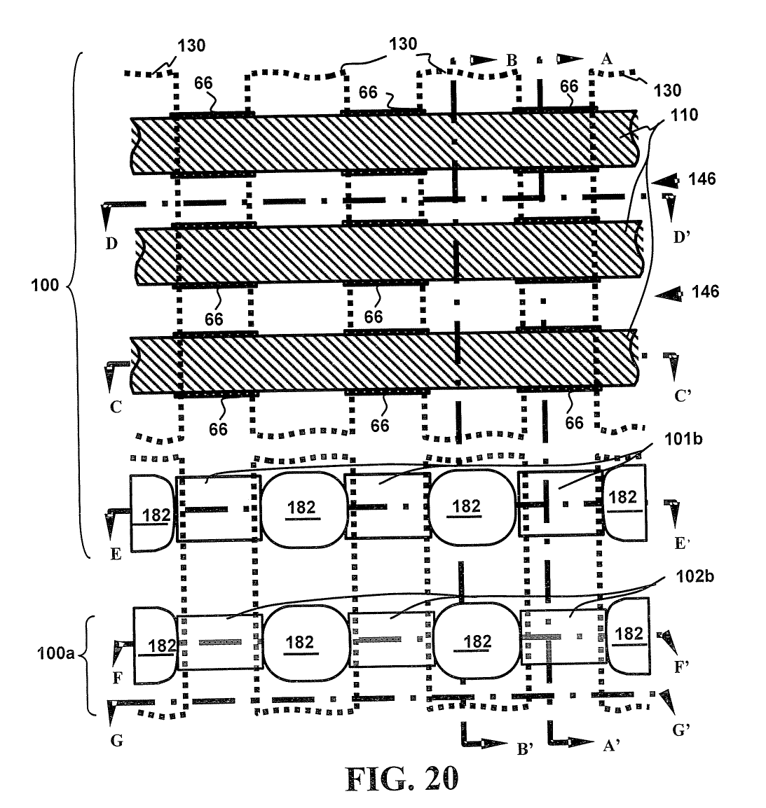

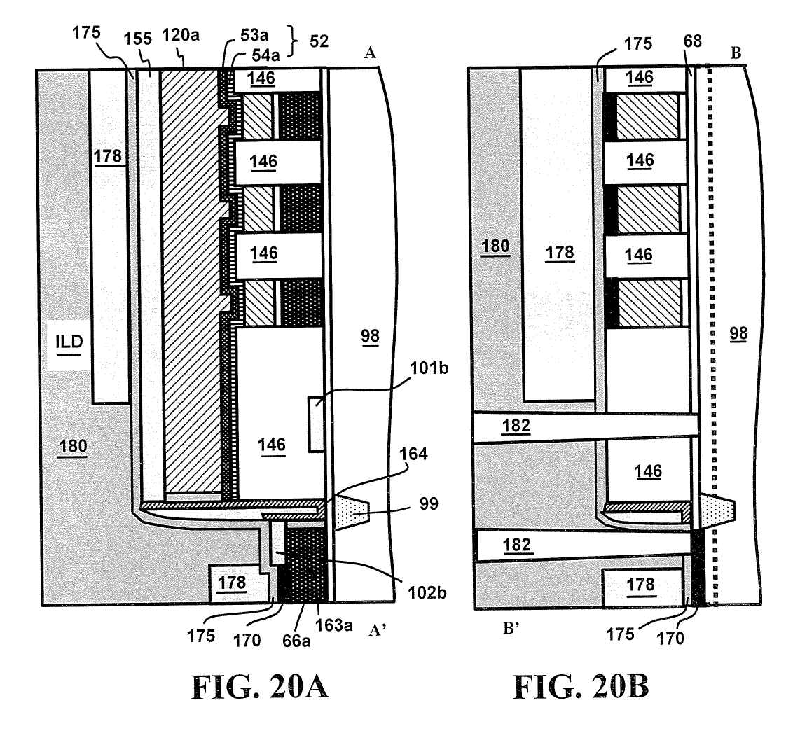

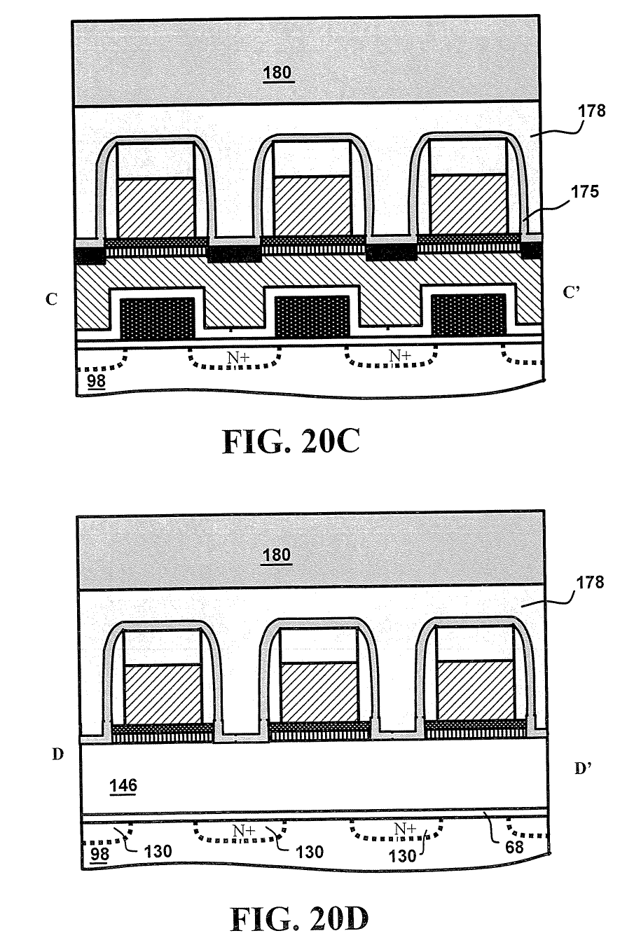

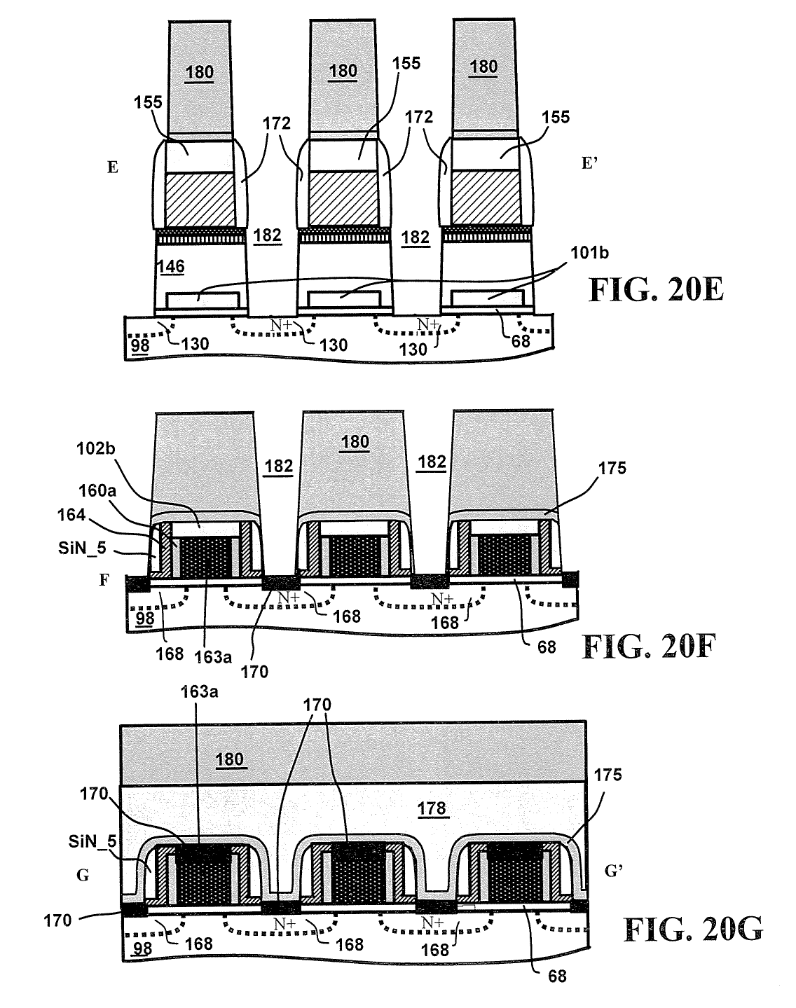

FIG. 20, FIG. 20A, FIG. 20B, FIG. 20C, FIG. 20D, FIG. 20E, FIG. 20F and FIG. 20G represent elements and steps in connection with forming contact holes and other elements.

The steps include removing the PR by using conventional PR striping techniques.

The steps include arranging an ILD dielectric layer 180 by for example depositing an oxide layer with a thickness in the range from 100 nm to 400 nm.

The steps include arranging a photo-resist (PR) on top of the structure using conventional photo-lithography techniques.

The steps include applying a first type of contact mask to define the PR exposing a portion of the ILD 180. This step defines contact holes 182 for self-aligned contacts (SAC). Such contacts are preferably formed over the bit lines 130 with each contact hole formed in between two adjacent nitride elements 101b (FIG. 37).

The steps include removing the exposed ILD layer 180, the thin oxide layer 175 using conventional etching technique to expose the oxide region 146. This step is followed by a RIE etch to remove the exposed oxide region 146. The etch step continues to remove the oxide layer 68 to expose the substrate 98.

The steps include an optional ion implantation to implant impurity (e.g. n-type impurity such as As) into silicon exposed in the contact holes. The energy of the implant is preferably chosen to prevent impurity implanting through the nitride elements 101b.

The steps include stripping the photo-resist. The resulting structure and their cross-sections are shown in FIG. 20, FIG. 20A, FIG. 20B, FIG. 20C, FIG. 20D, FIG. 20E, FIG. 20F and FIG. 20G, respectively.

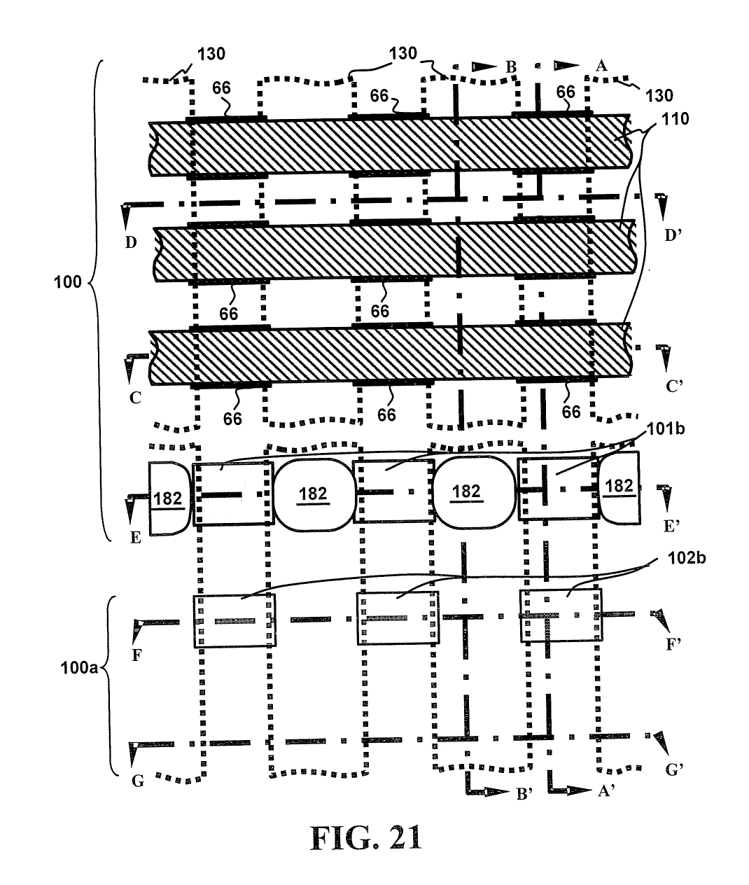

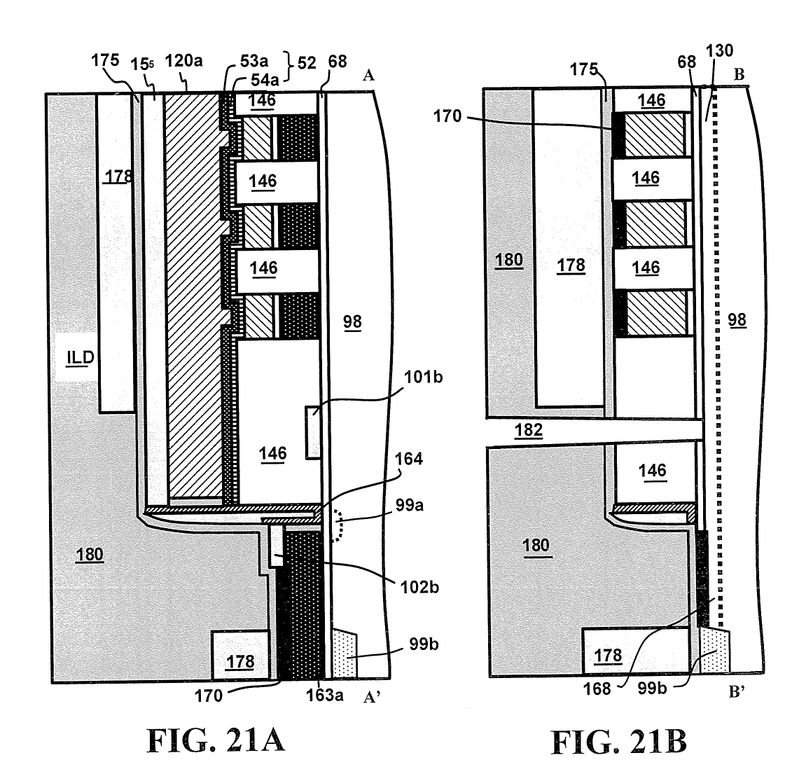

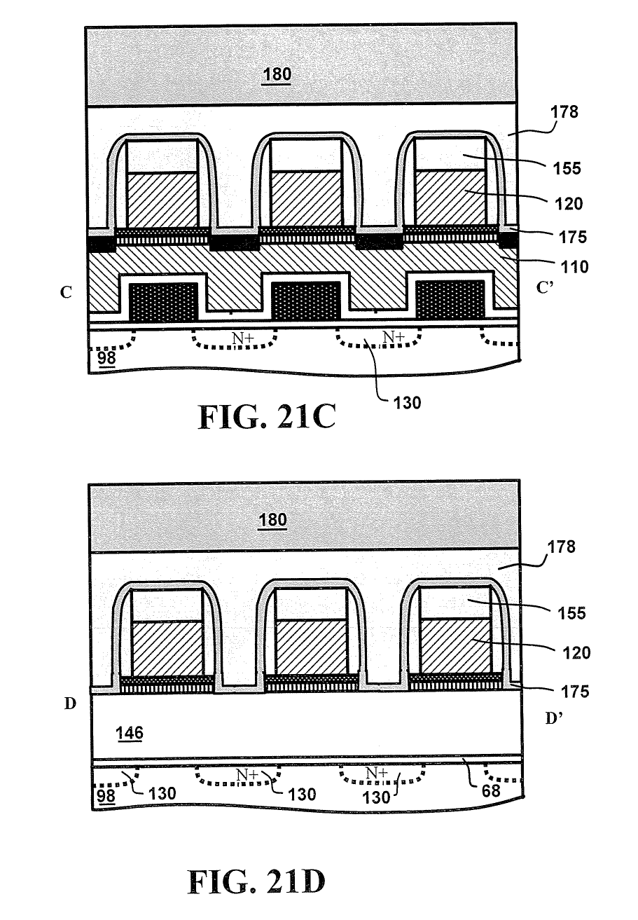

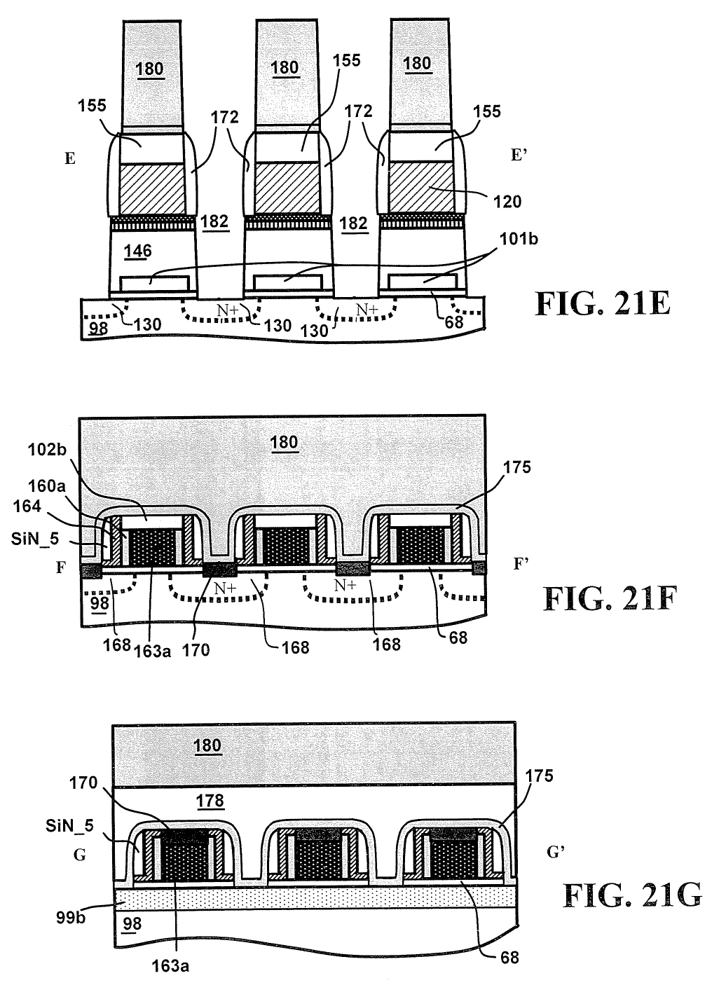

FIG. 21, FIG. 21A, FIG. 21B, FIG. 21C, FIG. 21D, FIG. 21E and FIG. 21F represent elements and steps in connection with junctions.

The steps include removing the exposed ILD layer 180 using conventional etching techniques to expose the second thick nitride layer 178 (As mentioned in the description in connection with FIG. 24, the isolation region 99 can be formed by employing a junction. Junction as the isolation scheme provides advantages on a simpler scheme in achieving more compact design for the decoder circuit in memory pitch region. Moreover, junction isolation can be used in together with STI isolation in a memory array. FIG. 21, FIG. 21A, FIG. 21B, FIG. 21C, FIG. 21D, FIG. 21E and FIG. 21F, illustrate a resulting structure and their cross-sections having junction isolation 99a and STI isolation 99b as the isolation scheme using manufacturing method of the present invention.

The structure thus formed has each of the bit-lines 130, which resides within the memory-cell region 100, be connected to one of the source/drain diffusions 168 as illustrated in FIG. 21B. Further, it is shown that the self-aligned-contacts 182 in the source/drain diffusions that were shown in FIG. 20 are now removed in FIG. 21. Such scheme is desirable for a simpler design and provides advantages on scalability for design in pitch region. The structures in FIGS. FIG. 21, FIG. 21A, FIG. 21B, FIG. 21C, FIG. 21D, FIG. 21E and FIG. 21F, provides an alternate embodiment for the structures shown in FIG. 20, FIG. 20A, FIG. 20B, FIG. 20C, FIG. 20D, FIG. 20E, FIG. 20F and FIG. 20G.

FIG. 22, FIG. 22A, FIG. 22C, and FIG. 22G represent elements and steps in connection with processing borderless contacts.

Borderless contacts are formed on structures of the present invention with illustration made to the alternate embodiment shown in FIGS. FIG. 21, FIG. 21A, FIG. 21B, FIG. 21C, FIG. 21D, FIG. 21E and FIG. 21F in following steps:

The steps include arranging a photo-resist (PR) on top of the structure using conventional photo-lithography techniques followed by applying a second type of contact mask to define the PR exposing ILD layer 180. This step defines area for contact holes 184 for borderless contacts. The contact holes 184 are made for contacting regions including word-lines 110, TG lines 120 of memory, gate 163a and source/drain 168 of logic transistors.

The steps include removing the exposed ILD layer 180 using conventional etching technique to expose the second thick nitride layer 178 (in logic transistor and in WL strap regions) and the first thick nitride 155 in TG line strap regions. The etch stops on the exposed nitride layers 178 and 155.

The steps include removing the exposed thick nitride layers 178 and 155 using conventional nitride etching technique followed by an oxide etch removing the thin oxide layer 175 in logic transistor region and in WL strap region. This step exposes salicide 170 in contact holes 184 for logic transistor and in contact holes 184 for WL conductor 62a. The nitride etch also exposes the TG conductor of the TG lines 120 (contact holes not shown).

An optional ion implantation is performed to implant impurity (e.g. n-type impurity such as As) into silicon exposed in the contact holes 184.

The steps include stripping the photo-resist. The resulting structure and their cross-sections are shown in FIG. 22, FIG. 22A, FIG. 22C, and FIG. 22G. Cross-sections along other directions are identical to the corresponding figures in FIG. 21s.

The structure is further processed by forming metal lines to form metallization to finish conventional IC fabrication.

In FIG. 22, FIG. 22A, FIG. 22C, and FIG. 22G, Borderless Contact holes are arranged. The contact holes 184 for borderless contactsare made for contacting regions including first lines 110 (for example, word-lines), TG lines 120 of memory, gate 163a and source/drain 168 of logic transistors.

For the junction isolation example, the material for region 99a has the same type of conductivity as that of the substrate 98 but typically with a higher concentration of doping. The region thus formed isolates one side 98-1 of region 99a from the other side 98-2 of region 99a at the surface of substrate 98. Typically this region 99a can have a rectangular shape in a top view or any other shape desired.

While the invention has been particularly shown and described with reference to preferred embodiments thereof it will be understood by those skilled in the art that various changes in arrange and details may be made therein without departing from the scope of the invention.

1. A memory device comprising,
a memory region including,
a plurality of memory cells, each memory cell including,
a source, a drain and a channel between the source and the drain,
a channel dielectric,
a charge storage region,
an electrically alterable conductor-material system in proximity to the charge storage region,
a plurality of conductor lines,
a non-memory region having embedded logic including a plurality of transistors, each transistor for electrically coupling one of the conductor lines and each transistor including a transistor source, a transistor drain and a transistor gate.

2. The memory device of claim 1 wherein the charge storage regions of a plurality of memory cells are substantially in alignment with the transistor gate of one of the transistors.

3. The memory device of claim 1 wherein,
the conductor lines include first and second cell lines connecting respectively to sources and drains of a first group of memory cells,
for a first one of the transistors, the transistor source is located substantially in alignment with one of the first and second cell lines and the transistor drain is located substantially in alignment with another one of the first and second cell lines.

4. The memory device of claim 3 wherein a plurality of transistors are connected where for the plurality of transistors the drain of one transistor is connected to the source of an adjacent transistor.

5. The memory device of claim 1 wherein,
the conductor lines include a plurality of first cell lines wherein the charge storage regions are substantially aligned between pairs of the first cell lines.

6. The memory device of claim 1 wherein the plurality of conductor lines includes one or more first cell lines extending to the non-memory region where one or more of the first cell lines electrically couples the embedded logic without an intermediary element or with a conductive intermediary element.

7. The memory device of claim 6 wherein the conductive intermediary element is selected from the group consisting of contacts, diffusions, metal lines and transistors or combinations thereof.

8. The memory device of claim 1 wherein,
the conductor lines include,
a plurality of first cell lines where the charge storage regions are substantially aligned between pairs of the first cell lines,
a plurality of second cell lines for electrically coupling to the charge storage regions of a plurality of memory cells.

9. The memory device of claim 1 wherein,
the conductor lines include,
a plurality of first cell lines wherein the charge storage regions are substantially aligned between pairs of the first cell lines,
a plurality of second cell lines for electrically coupling to the charge storage regions,
a plurality of third cell lines, each third cell line arrayed substantially between a pair of the first cell lines and substantially aligned with the charge storage regions substantially between the pair of the first cell lines.

10. The memory device of claim 9 wherein the third cell lines are covered by nitride material.

11. The memory device of claim 1 further comprising,
a plurality of first contacts arrayed substantially aligned with ones of the conductor lines,
a plurality of second contacts arrayed substantially aligned with ones of the conductor lines,
wherein said first contacts and said second contacts are selected from the group consisting of self-aligned contacts, borderless contacts and combinations thereof.

12. The memory device of claim 1 wherein,
the conductor lines include,
a plurality of first cell lines wherein the charge storage regions are substantially aligned between pairs of the first cell lines,
a plurality of second cell lines for electrically coupling to the charge storage regions,
a plurality of third cell lines, each third cell line arrayed substantially between a pair of the first cell lines and substantially aligned with the charge storage regions substantially between the pair of the first cell lines,
and wherein the electrically alterable conductor-material system includes a filter between the second cell lines and the third cell lines.

13. The memory device of claim 12 wherein a salicide region is located substantially between each pair of third cell lines with the salicide region in contact with the second cell line.

14. The memory device of claim 1 wherein,
the conductor lines include memory cell lines in the memory cell region and transistor lines in the non-memory cell region where the memory cell lines and the transistor lines are substantially aligned.

15. The memory device of claim 14 wherein the transistor lines form a source and a drain of a transistor.

16. The memory device of claim 14 wherein, the memory cell lines are isolated from the transistor lines by an isolation.

17. The memory device of claim 16 wherein the isolation is selected from the group consisting of LOCOS isolation, shallow-trench isolation and junction isolation and combinations thereof.

18. The memory device of claim 1 further including one or more conductor line contacts in one or more contact holes substantially aligned with one or more conductor lines whereby the one or more conductor line contacts electrically couple to the one or more conductor lines.

19. The memory device of claim 1 wherein,
a plurality of contact insulators are arrayed substantially between pairs of the conductor lines,
pairs of the contact insulators align conductor line contacts in contact holes substantially there between whereby the conductor line contacts electrically couple to the conductor lines.

20. The memory device of claim 19 wherein,
the conductor lines include memory cell lines in the memory cell region and transistor lines in the non-memory cell region and wherein the memory cell lines and the transistor lines are substantially aligned,
pairs of cell line contact insulators align cell line contacts in contact holes there between whereby the cell line contacts electrically couple to the memory cell lines,
pairs of transistor line contact insulators align transistor contacts in contact holes there between whereby the transistor contacts electrically couple to the transistor lines.

21. The memory device of claim 20 wherein the contact insulators are one or more materials selected from the group consisting of oxide, nitride, oxynitride and alloys thereof.

22. The memory device of claim 20 wherein the electrical coupling to the transistor lines is through salicide regions contacting the transistor lines.

23. A memory device comprising,
a memory region including,
a plurality of memory cells arrayed at a cell pitch, each memory cell including,
a source, a drain and a channel between the source and the drain,
a channel dielectric,
a charge storage region,
an electrically alterable conductor-material system in proximity to the charge storage region,
a plurality of conductor lines arrayed substantially at the cell pitch,
a non-memory region having embedded logic including a plurality of transistors arrayed substantially at the cell pitch, each transistor for electrically coupling one of the conductor lines and each transistor including a transistor source, a transistor drain and a transistor gate.

24. The memory device of claim 23 wherein the charge storage regions of a plurality of memory cells are substantially in alignment with the transistor gate of one of the transistors.

25. A method of arranging a memory device comprising,
in a memory region,
arranging a memory cell region including,
arranging a plurality of memory cells, including for each memory cell,
arranging a source, a drain and a channel between the source and the drain,
arranging a channel dielectric,
arranging a charge storage region,
arranging an electrically alterable conductor-material system in proximity to the charge storage region,
arranging a plurality of conductor lines,
in a non-memory region arranging embedded logic including arranging a plurality of transistors, each transistor arranged for electrically coupling one of the conductor lines and each transistor including the steps of arranging a transistor source, arranging a transistor drain and arranging a transistor gate.
